(19) United States
(12) Patent Application Publication
(10) Pub. No.: US 2025/0359128 A1
(43) Pub. Date: Nov. 20, 2025

(54) Tunnel Field Effect Transistor and Method of Fabrication Thereof

(71) Applicant: Taiwan Semiconductor Manufacturing Company, Ltd., Hsin-Chu (TW)

(72) Inventors: Yi-Hong WANG, Taichung City (TW); Yi-Chen LI, Taichung City (TW)

(21) Appl. No.: 19/288,593

(22) Filed: Aug. 1, 2025

Related U.S. Application Data
(63) Continuation of application No. 18/606,175, filed on Mar. 15, 2024.
(60) Provisional application No. 63/587,289, filed on Oct. 2, 2023.

(51) Int. Cl. H10D 30/60; H10D 30/01; H10D 64/01

(52) U.S. Cl. CPC H10D 30/603; H10D 30/0221; H10D 64/017

(57) ABSTRACT

Asymmetry may be used to tune electrical properties of tunnel field effect transistors (TFETs). An exemplary TFET includes a gate stack disposed over a semiconductor layer, a source disposed in the semiconductor layer, and a drain disposed in the semiconductor layer. The gate stack includes a gate electrode disposed over a gate dielectric. The gate stack is disposed between the source and the drain. The source has a first conductivity type, and the drain has a second conductivity type different than the first conductivity type. The gate stack is asymmetric. For example, the gate stack has an asymmetric gate dielectric, an asymmetric gate electrode, asymmetric gate footing, asymmetric sidewalls, or combinations thereof. In some embodiments, the source and the drain have asymmetric profiles. In some embodiments, the semiconductor layer is a semiconductor fin, and the gate stack wraps the semiconductor fin.

This is a continuation application of U.S. patent application Ser. No. 18/606,175, filed Mar. 15, 2024, which is a non-provisional application of and claims benefit of U.S. Provisional Patent Application Ser. No. 63/587,289, filed Oct. 2, 2023, the entire disclosures of which are incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (e.g., minimum IC feature sizes), thereby improving production efficiency and lowering associated costs. For examples, reducing sizes of transistors (and thus reducing dimensions thereof) in ICs may reduce power supply voltages and/or threshold voltages needed for operating the transistors.

However, for metal-oxide-semiconductor field-effect transistors (MOSFETs), lower threshold voltages are difficult to obtain because leakage current has been observed to increase (sometimes exponentially) as threshold voltages decreases and subthreshold swing (SS) of MOSFETs is limited to about 60 mV/dec. Tunneling field effect transistors (TFETs), which use band-to-band tunneling (BTBT), are thus being explored to replace MOSFETs. Although existing TFETs and methods for fabricating such have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a perspective view of a tunneling field effect transistor (TFET), in portion or entirety, according to various aspects of the present disclosure.

FIG. 2A and FIG. 2B are top views of a portion of TFET of FIG. 1, with and without an electric field overlaid thereon, according to various aspects of the present disclosure.

FIG. 3 is a cross-sectional view of the TFET of FIG. 1, in portion or entirety, along line A-A, according to various aspects of the present disclosure.

FIG. 4 is a cross-sectional view of the TFET of FIG. 1, in portion or entirety, along line B-B, according to various aspects of the present disclosure.

FIG. 5 is a cross-sectional view of the TFET of FIG. 1, in portion or entirety, along line C-C, according to various aspects of the present disclosure.

FIG. 6 is a cross-sectional view of the TFET of FIG. 1, in portion or entirety, along line D-D, according to various aspects of the present disclosure.

FIG. 7 are top views of the TFET of FIG. 1, in portion or entirety, cut through line E-E and line F-F, respectively, according to various aspects of the present disclosure.

FIG. 8 is a cross-sectional view of another configuration of the TFET of FIG. 1, in portion or entirety, along line A-A, according to various aspects of the present disclosure.

FIG. 9 is the cross-sectional view of the TFET of FIG. 1, in portion or entirety, along line A-A with tunneling paths depicted, according to various aspects of the present disclosure.

FIG. 10 is a top view of another configuration of the TFET of FIG. 1, in portion or entirety, according to various aspects of the present disclosure.

FIG. 11 is a cross-sectional view of another configuration of the TFET of FIG. 1, in portion or entirety, along line A-A according to various aspects of the present disclosure.

FIG. 12 is a flow chart of a method for fabricating a TFET, in portion or entirety, according to various aspects of the present disclosure.

FIGS. 13A-23A are top views of a TFET, in portion or entirety, at various fabrication stages of the method of FIG. 12, according to various aspects of the present disclosure.

FIGS. 13B-23B and FIGS. 13C-23C are cross-sectional views of the TFET of FIGS. 13A-23A, respectively, according to various aspects of the present disclosure.

FIG. 24 depicts a device, in portion or entirety, that includes various transistors, such as the TFET of FIG. 1, according to various aspects of the present disclosure.

### DETAILED DESCRIPTION

The present disclosure is generally directed to tunnel field effect transistors (TFETs) with improved tunneling and methods of fabrication thereof.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features—but not mathematically or perfectly vertical and horizontal.

Details of improved tunnel field effect transistors (TFETs), along with methods of fabrication thereof, are described herein. As described herein, gate stack asymmetry (e.g., gate dielectric asymmetry, gate electrode asymmetry, gate footing asymmetry, gate sidewall asymmetry, etc.) and/or source/drain asymmetry is used to tune and optimize electrical properties of TFETs. TFETs disclosed herein may improve gate control adjacent to a source, reduce gate induced drain leakage, reduce ambipolar leakage, increase an electric field in a source area/region, decrease an electric field in a drain area/region, increase/enlarge band-to-band tunneling probability, provide a gate dielectric with variable sensitivity to a gate voltage (e.g., more sensitivity in source area/region and less sensitivity in a drain area/region), reduce a gate length, improve saturation current, improve threshold voltage, provide other advantages, or combinations thereof. In some embodiments, TFETs described herein may be operated with supply voltages that are less than about 0.5 V. Different embodiments may have different advantages, and no particular advantage is required of any embodiment.

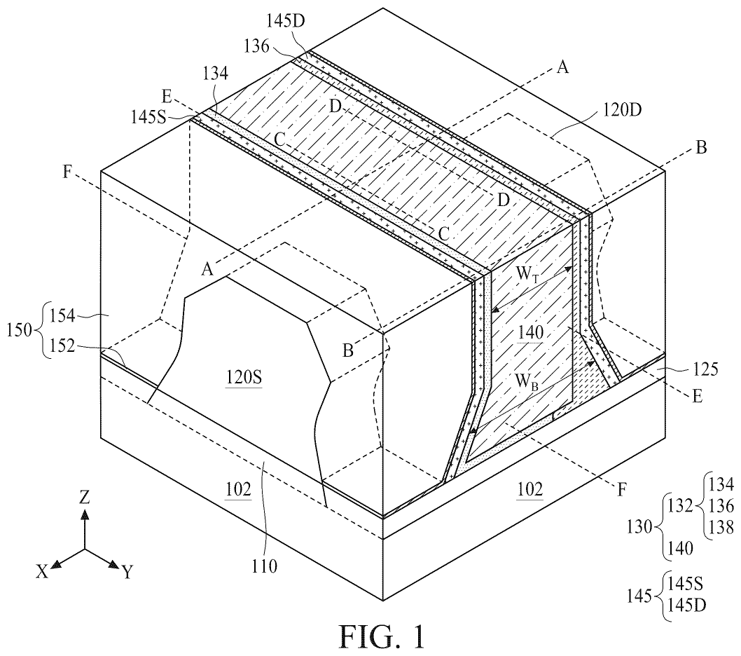

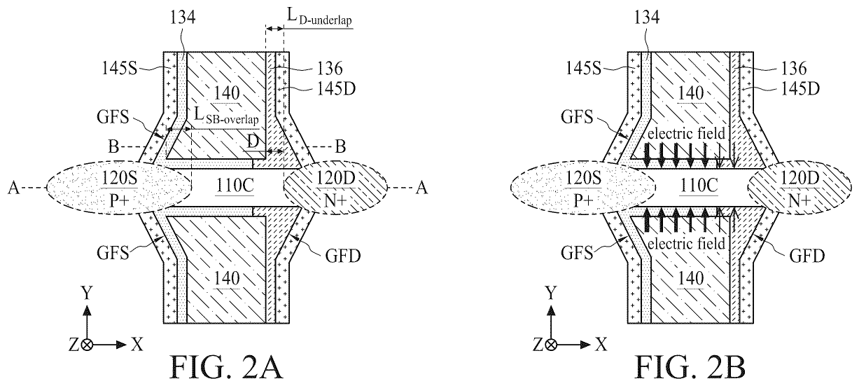

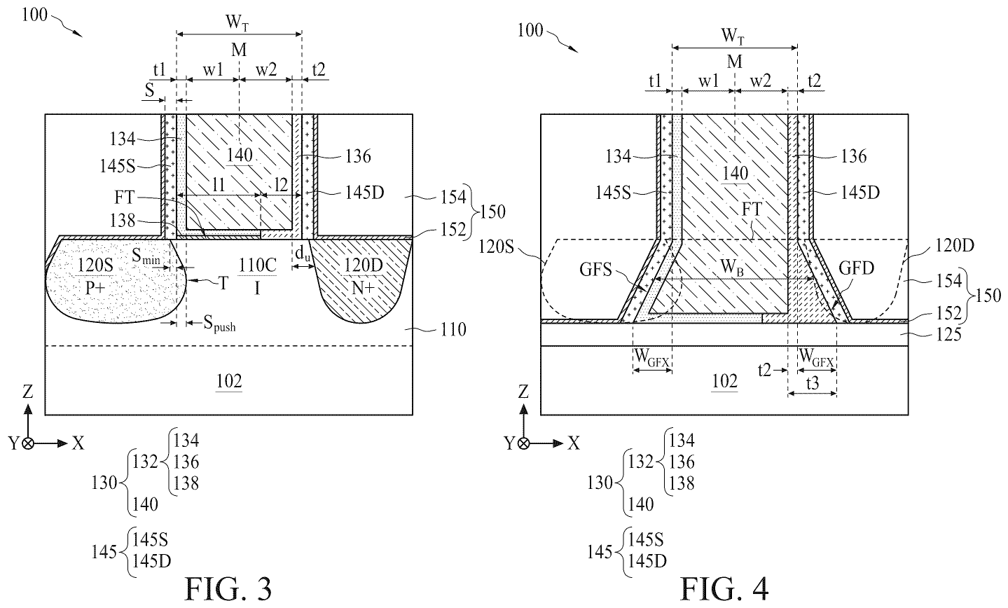

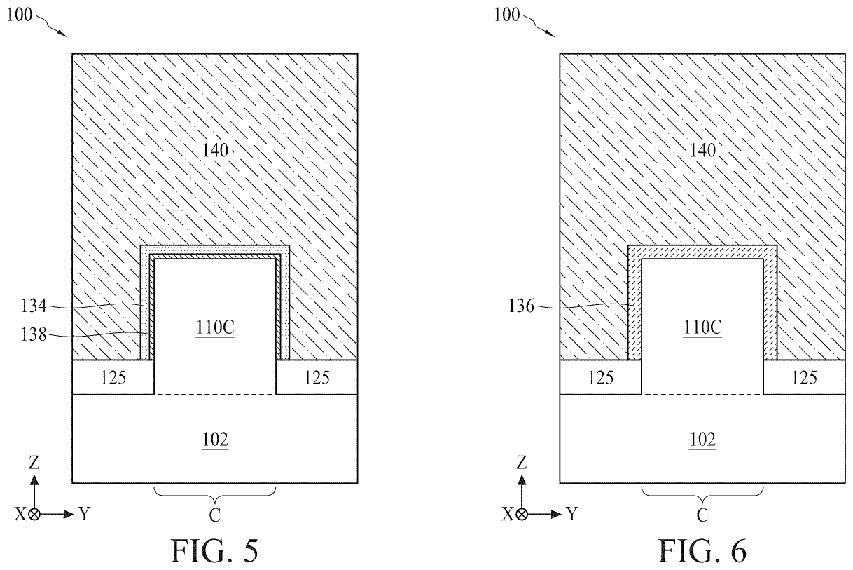

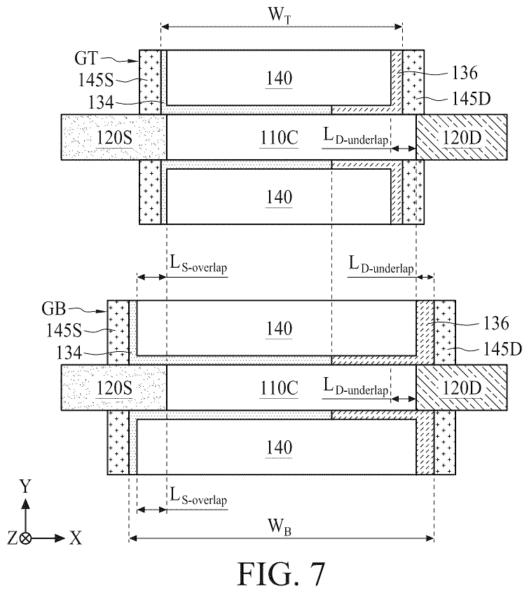

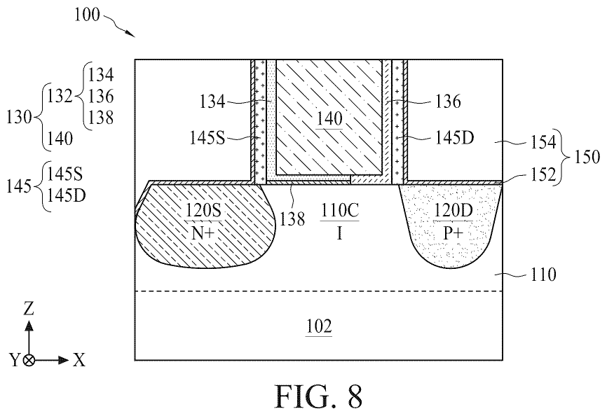

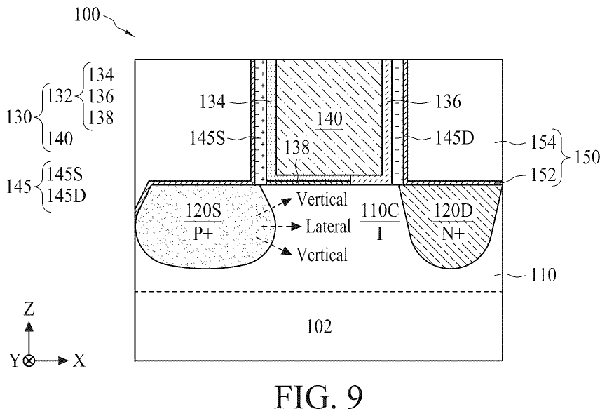

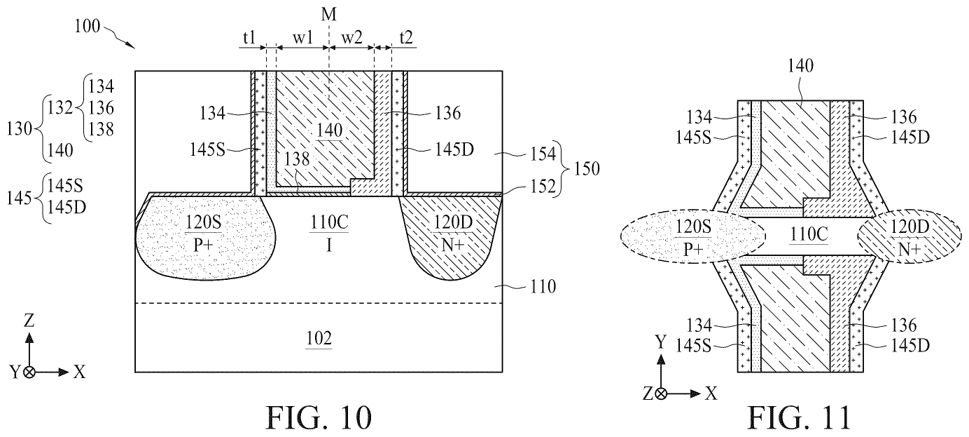

FIG. 1 is a perspective view of a tunneling field effect transistor (TFET) 100, in portion or entirety, according to various aspects of the present disclosure. FIG. 2A and FIG. 2B are top views of a portion of TFET of FIG. 1, with and without an electric field superimposed thereon, according to various aspects of the present disclosure. FIG. 3 is a cross-sectional view of TFET 100, in portion or entirety, along line A-A of FIG. 1, according to various aspects of the present disclosure. FIG. 4 is a cross-sectional view of TFET 100, in portion or entirety, along line B-B of FIG. 1, according to various aspects of the present disclosure. FIG. 5 is a cross-sectional view of TFET 100, in portion or entirety, along line C-C of FIG. 1, according to various aspects of the present disclosure. FIG. 6 is a cross-sectional view of TFET 100, in portion or entirety, along line D-D of FIG. 1, according to various aspects of the present disclosure. FIG. 7 are top views of TFET 100, in portion or entirety, cut through line E-E and line F-F of FIG. 1, respectively, according to various aspects of the present disclosure. FIG. 8 is a cross-sectional view of another configuration of TFET 100, in portion or entirety, according to various aspects of the present disclosure. FIG. 9 is the cross-sectional view of TFET 100, in portion or entirety, along line A-A of FIG. 1 with tunneling paths superimposed thereon, according to various aspects of the present disclosure. FIG. 10 and FIG. 11 are a top view and a cross-sectional view along line A-A, respectively, of another configuration of the TFET of FIG. 1, in portion or entirety, according to various aspects of the present disclosure. FIG. 1, FIG. 2A, FIG. 2B, and FIGS. 3-11 are discussed concurrently herein for case of description and understanding. FIG. 1, FIG. 2A, FIG. 2B, and FIGS. 3-11 have been simplified for the sake of clarity to better understand the inventive concepts of the present disclosure. Additional features may be added in TFET 100, and some of the features described below may be replaced, modified, or eliminated in other embodiments of TFET 100.

TFET 100 may be formed over and/or include a substrate 102. In the depicted embodiment, substrate 102 is a silicon substrate. Substrate 102 may include an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 102 is a semiconductor-on-insulator substrate, such as a silicon-on-insulator (SOI) substrate, a silicon germanium-on-insulator (SGOI) substrate, or a germanium-on-insulator (GOI) substrate. Substrate 102 may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, other p-type dopant, or combinations thereof. In some embodiments, the doped regions include p-type dopants and n-type dopants. The doped regions may be formed directly on and/or in substrate 102, for example, providing a p-well structure, an n-well structure, a dual-well structure, a raised structure, other suitable structure, or combinations thereof.

TFET 100 has a channel 110C, a source 120S, and a drain 120D. In the depicted embodiment, source 120S and drain 120D are disposed in a fin 110 extending from substrate 102, and channel 110C is formed in a portion of fin 110 disposed between source 120S and drain 120D. Fin 110 extends along the x-direction, having a length along the x-direction, a width along a y-direction, and a height along a z-direction. In some embodiments, fin 110 is a semiconductor fin that includes silicon, germanium, silicon germanium, other suitable semiconductor material, or combinations thereof. In some embodiments, fin 110 is formed from a portion of substrate 102. For example, substrate 102 may be a silicon substrate, and fin 110 may be a patterned portion and/or extension of substrate 102 (i.e., a silicon fin). In some embodiments, fin 110 is formed from one or more semiconductor layers deposited and patterned over substrate 102. For example, substrate 102 may be a silicon substrate, and fin 110 may be formed from a silicon germanium layer deposited and patterned over substrate 102 (i.e., a silicon germanium fin). In some embodiments, a composition and/or a material of fin 110 is selected based on a type of TFET to which fin 110 belongs and/or a desired channel material.

TFET 100 has asymmetric source/drains. For example, source 120S and drain 120D are doped with opposite type dopants (i.e., source 120S and drain 120D have opposite conductivities). In the depicted embodiment, source 120S is doped with p-type dopant (e.g., boron, gallium, indium, other p-type dopant, or combinations thereof), and drain 120D is doped with n-type dopant (e.g., phosphorus, arsenic, other n-type dopant, or combinations thereof). In some embodiments, source 120S is a heavily doped p-type (P+) region and drain 120D is a heavily doped n-type (N+) region. For example, source 120S may have a p-type dopant concentration that is about 1×10¹⁹ atoms/cm³ (cm⁻³) to about 1×10²¹ cm⁻³ and drain 120D may have an n-type dopant concentration that is about 1×10¹⁹ cm⁻³ to about 1×10²¹ cm⁻³. In some embodiments, channel 110C is an intrinsic (I) region, such as an undoped/unintentionally doped (UID) region or a lightly doped region of fin 110. For example, channel 110C may be formed of an intrinsic semiconductor material (e.g., monocrystalline silicon), which is an undoped and/or unintentionally doped (UID) semiconductor material (i.e., without or having negligible p-type dopant and/or n-type dopant). In another example, channel 110C may be formed of a semiconductor material having a dopant concentration, such as a p-type dopant concentration and/or an n-type dopant concentration, that is less than about 1×10¹⁵ cm⁻³.

In addition to different conductivities, source 120S and drain 120D may include different materials, such as different bandgap materials. For example, source 120S may include a first material having a first bandgap (a “small-bandgap” material) and drain 120D may include a second material having a second bandgap (a “large-bandgap” material) that is greater than the first bandgap. In some embodiments, the small-bandgap material and the large-bandgap material have an energy band gap that is less than about 1.2 electronvolts (eV). Source 120S and/or drain 120D includes silicon (Si), germanium (Ge), gallium (Ga), antimony (Sb), indium (In), arsenic (As), phosphorous (P), aluminum (Al), tin (Sn), other suitable constituent, or combinations thereof. For example, source 120S includes GaSb, InAs, InGaAs, SiGe, SiP, GeSn, InSb, GaAsSb, other semiconductor-comprising material, or combinations thereof, and drain 120D includes GaSb, InAs, InGaAs, SiGe, SiP, GeSn, InSb, GaAsSb, other semiconductor-comprising material, or combinations thereof. In some embodiments, source 120S and/or drain 120D include a two-dimensional material, such as graphene. In some embodiments, source 120S and/or drain 120D include a metal compound and/or a metal alloy. In some embodiments, source 120S and/or drain 120D includes more than one semiconductor layer, where the semiconductor layers include the same or different materials and/or the same or different dopant concentrations. In some embodiments, source 120S and/or drain 120D are formed using epitaxial growth processes (e.g., selective epitaxial growth (SEG)), and source 120S and drain 120D are referred to as an epitaxial source and an epitaxial drain, respectively.

Channel 110C includes silicon (Si), germanium (Ge), gallium (Ga), antimony (Sb), indium (In), arsenic (As), carbon (C), molybdenum (Mo), sulfur(S), tungsten (W), selenium (Sc), other suitable constituent, or combinations thereof. For example, channel 110C may be formed in and/or formed of SiGe, InGaAs, InAs, GaAsSb, other semiconductor-comprising material, or combinations thereof. In some embodiments, channel 110C is formed in and/or formed of a two-dimensional material, such as molybdenum disulfide (MoS₂), tungsten selenide (WSe₂), carbon nanotube (CNT), or combinations thereof. In some embodiments, channel 110C is formed in and/or formed of a metal compound and/or a metal alloy. In some embodiments, channel 110C is formed in and/or formed of a third material having a third bandgap (a “large-bandgap” material) that is greater than the first bandgap of the first material of source 120S, and the third bandgap may be different than the second bandgap of the second material of drain 120D. In some embodiments, the third bandgap is less than about 1.2 eV.

In the depicted embodiment, TFET 100 is configured as an n-type TFET (N-TFET) having a P+ source and an N+ drain. In some embodiments, source 120S is a P+ SiGe source, channel 110C is a Si channel, and drain 120D is an N+ SiP drain. In some embodiments, source 120S is a P+ InAs source, channel 110C is an InAs channel, and drain 120D is an N+ GaSb drain. In some embodiments, source 120S is a P+ Ge source, channel 110C is a Si channel, and drain 120D is an N+ SiP drain. In some embodiments, channel 110C is a Si channel, and source 120S is a P+ Si source, a P+ SiGe source, a P+ Ge source, a P+ GeSn source, or combinations thereof. TFET 100, as depicted in FIG. 1, is not limited to the example material configurations of source 120S, channel 110C, and drain 120D. The present disclosure contemplates an N-TFET having other material configurations of source 120S, channel 110C, and drain 120D.

In some embodiments, TFET 100 is configured as a p-type TFET (P-TFET) having an N+ source and a P+ drain, such as depicted in FIG. 8. In some embodiments, source 120S is an N+ Si source, channel 110C is a Si channel, and drain 120D is a P+ SiGe drain. In some embodiments, source 120S is an N+ GaSb source, channel 110C is an InGaAs channel, and drain 120D is a P+ InGaAs drain. In some embodiments, channel 110C is an InAs channel, and source 120S is an N+ GaSb source. In some embodiments, channel 110C is an InGaAs channel, and source 120S is an N+ InGaAs source, an N+ InP source, or combinations thereof. TFET 100, as depicted in FIG. 8, is not limited to the example material configurations of source 120S, channel 110C, and drain 120D. The present disclosure contemplates a P-TFET having other material configurations of source 120S, channel 110C, and drain 120D.

TFET 100 further includes a substrate isolation structure 125 that electrically isolates active regions (e.g., fin 110) from adjacent active regions. For example, substrate isolation structure 125 may separate and electrically isolate fin 110 from another fin of TFET 100 or from a fin and/or active region of another device, such as another transistor. Substrate isolation structure 125 includes silicon oxide, silicon nitride, silicon oxynitride, other suitable isolation material (including, for example, silicon, oxygen, nitrogen, carbon, other suitable isolation constituent, etc.), or combinations thereof. Substrate isolation structure 125 may have a multilayer structure. For example, substrate isolation structure 125 may include a bulk dielectric (e.g., an oxide layer) over a dielectric liner (including, for example, silicon nitride, silicon oxide, silicon oxynitride, silicon oxycarbonitride, or combinations thereof). In another example, substrate isolation structure 125 may include a dielectric layer over a doped liner, such as a boron silicate glass (BSG) liner and/or a phosphosilicate glass (PSG) liner. Dimensions and/or characteristics of substrate isolation structure 125 are configured to provide a shallow trench isolation (STI) structure, a deep trench isolation (DTI) structure, a local oxidation of silicon (LOCOS) structure, other suitable isolation structure, or combinations thereof. In the depicted embodiment, substrate isolation structure 125 may be an STI.

TFET 100 further includes a gate structure having a gate stack 130 and gate spacers 145. The gate structure is disposed on channel 110C (FIG. 1, FIG. 2A, FIG. 3, and FIGS. 5-7), the gate structure is disposed between source 120S and drain 120D (FIG. 1, FIG. 2A, FIG. 3, and FIG. 7), and the gate structure is disposed on substrate isolation structure 125 (FIG. 1 and FIG. 4). The gate structure extends lengthwise in a direction that is different than (e.g., orthogonal to) the lengthwise direction of fin 110. For example, the gate structure (e.g., gate stack 130 thereof) extends lengthwise along the y-direction, having a length along the y-direction, a width along the x-direction, and a height along the z-direction. In a cross-sectional view along a lengthwise direction of fin 110 (FIG. 3), the gate structure is disposed on a top of channel 110C of fin 110. In top views along a lengthwise direction of fin 110 (FIG. 2A and FIG. 6), the gate structure is disposed along sidewalls of channel 110C of fin 110. In cross-sectional views along a widthwise direction of fin 110 (FIG. 5 and FIG. 6), the gate structure is disposed over a top and sidewalls of channel 110C of fin 110, and the gate structure wraps channel 110C.

Gate stack 130 has an asymmetric gate dielectric 132 that may improve performance, such as band-to-band tunneling, of TFET 100. For example, gate dielectric 132 includes a source-side gate dielectric layer 134 and a drain-side gate dielectric layer 136. Source-side gate dielectric layer 134 and drain-side gate dielectric layer 136 form a source-facing/adjacent sidewall and a drain-facing/adjacent sidewall, respectively, of gate stack 130 (i.e., gate stack 130 has asymmetric sidewalls). In a cross-sectional view along the lengthwise direction of fin 110 (FIG. 3), source-side gate dielectric layer 134 is disposed on a top of a source-side portion of channel 110C and drain-side gate dielectric layer 136 is disposed on a top of a drain-side portion of channel 110C. In top views along the lengthwise direction of fin 110 (FIG. 2A and FIG. 7), source-side gate dielectric layer 134 and drain-side gate dielectric layer 136 extend along sidewalls of the source-side portion and the drain-side portion, respectively, of channel 110C. In cross-sectional views along the widthwise direction of fin 110 (FIG. 5 and FIG. 6), source-side gate dielectric layer 134 wraps the source-side portion of channel 110C (FIG. 5) and drain-side gate dielectric layer 136 wraps the drain-side portion of channel 110C (FIG. 6).

A dielectric constant of source-side gate dielectric layer 134 is greater than a dielectric constant of drain-side gate dielectric layer 136. Source-side gate dielectric layer 134 and drain-side gate dielectric layer 136 may thus be referred to as a high-k dielectric layer/portion and a low-k dielectric layer/portion, respectively, of gate dielectric 132. In some embodiments, source-side gate dielectric layer 134 has a dielectric constant greater than about 10 (k≥10) and drain-side gate dielectric layer 136 has a dielectric constant less than about 10 (k≤10). In the depicted embodiment, source-side gate dielectric layer 134 and drain-side gate dielectric layer 136 are a metal-and-oxygen comprising dielectric layer and a silicon-and-oxygen comprising dielectric layer, respectively. The metal of the metal-and-oxygen comprising dielectric layer is hafnium, zirconium, aluminum, lanthanum, zinc, titanium, tantalum, yttrium, strontium, barium, strontium, other suitable metal, or combinations thereof. The metal-and-oxygen comprising dielectric layer may further include silicon and/or nitrogen, and the silicon-and-oxygen comprising dielectric layer may further include nitrogen and/or carbon. In some embodiments, source-side gate dielectric layer 134 includes HfO₂, HfSiO, HfSiO₄, HESiON, HfLaO, HfTaO, HfTiO, HfZiO, HfAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZiO, BaTiO₃ (BTO), (Ba,Sr)TiO₃ (BST), HfO₂—Al₂O₃, other metal-and-oxygen comprising dielectric material, or combinations thereof. In some embodiments, source-side gate dielectric layer 134 is a hafnium-based oxide (e.g., HfO₂) layer, a zirconium-based oxide (e.g., ZrO₂) layer, or a lanthanum-based oxide (e.g., La₂O₃) layer. In some embodiments, drain-side gate dielectric layer 136 is an SiOₓN₁₋ₓ layer (where x is a number of oxygen atoms in a molecule of silicon oxynitride), an SiCₓO_{y}N_{1-x-y} layer (where x is a number of carbon atoms and y is a number of oxygen atoms in a molecule of silicon oxycarbonitride), or an SiO₂ layer. In some embodiments, source-side gate dielectric layer 134 and drain-side gate dielectric layer 136 each include a single layer, such as depicted. In some embodiments, source-side gate dielectric layer 134 has a multilayer structure. In some embodiments, drain-side gate dielectric layer 136 has a multilayer structure.

Gate dielectric 132 may further include an interfacial layer 138. In the depicted embodiment, interfacial layer 138 is disposed between source-side gate dielectric layer 134 and channel 110C. In some embodiments, interfacial layer 138 is also disposed between drain-side gate-dielectric layer 136 and channel 110C. Interfacial layer 138 includes a dielectric material, such as SiO₂, SiGeOₓ, HfSiO, SiON, other dielectric material, or combinations thereof. Interfacial layer 138 may be in the active region of TFET 100 (e.g., fin 110), but not the isolation region of TFET 100 (e.g., substrate isolation structure 125). For example, in the active region, interfacial layer 138 may cover a top of channel 110C of fin 110 (FIG. 3), and interfacial layer 138 may wrap channel 110C (FIG. 6). In some embodiments, interfacial layer 138 has a substantially uniform thickness, such as in the depicted embodiment.

Gate stack 130 further has a gate electrode 140 disposed on gate dielectric 132. Gate electrode 140 is disposed on both source-side gate dielectric layer 134 and drain-side gate dielectric layer 136. In top views along the lengthwise direction of fin 110 (FIG. 2A and FIG. 7), gate electrode 140 extends along sidewalls of the source-side portion and the drain-side portion, respectively, of channel 110C. In cross-sectional views along the widthwise direction of fin 110 (FIG. 6 and FIG. 7), gate electrode 140 is disposed over the top and the sidewalls of the source-side portion of channel 110C (FIG. 6) and the drain-side portion of channel 110C (FIG. 7) (i.e., gate electrode 140 wraps channel 110C of fin 110). As described further herein, gate electrode 140 may be asymmetric or symmetric in gate stack 130 depending on its location (e.g., a portion of gate stack 130 in the active region may be symmetric, while a portion of gate stack 130 in the isolation region may be asymmetric), dimensions of source-side gate dielectric layer 134, dimensions of drain-side gate dielectric layer 136, other factors, or combinations thereof.

Gate electrode 140 includes at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments gate electrode 140 includes a work function layer. The work function layer is an electrically conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, gate electrode 140 includes a bulk layer over gate dielectric 132 and/or the work function layer. The bulk layer includes a suitable conductive material, such as Al, W, Cu, Ti, Ta, TiN, TaN, polysilicon, other suitable metal(s) and/or alloys thereof, or combinations thereof. In some embodiments, gate electrode 140 includes a barrier layer over the work function layer and/or gate dielectric 132. The barrier layer includes a material that may prevent or eliminate diffusion and/or reaction of constituents between adjacent layers and/or may promote adhesion between adjacent layers, such as between the work function layer and the bulk layer. In some embodiments, the barrier layer includes metal and nitrogen, such as TiN, TaN, W₂N, TiSiN, TaSiN, other suitable metal nitride, or combinations thereof.

Gate spacers 145 (which collectively refers to a source-side gate spacer 145S and a drain-side gate spacer 145D) are adjacent to and along sidewalls of gate stack 130. Source-side gate spacer 145S and drain-side gate spacer 145D are separated from gate electrode 140 by source-side gate dielectric layer 134 and drain-side gate dielectric layer 136, respectively. Gate spacers 145 may include seal spacers, offset spacers, sacrificial spacers, dummy spacers, main spacers, other suitable spacers, or combinations thereof. Gate spacers 145 may each be a single layer or have a multilayer structure. Gate spacers 145 include a dielectric material, which may include silicon, oxygen, carbon, nitrogen, other suitable constituent, or combinations thereof (e.g., silicon oxide, silicon nitride, silicon oxynitride, silicon carbide, silicon carbonitride, silicon oxycarbide, silicon oxycarbonitride, etc.). In the depicted embodiment, s composition of gate spacers 145 is different than a composition of drain-side gate dielectric layer 136. For example, gate spacers 145 include silicon and nitrogen and/or carbon, and gate spacers 145 may further include oxygen and/or hydrogen. For example, gate spacers 145 include SiN layers, SiC layers, or SiCN layers, which may be directly adjacent to sidewalls of gate stack 130.

A dielectric layer 150 is disposed over substrate 102, source 120S, drain 120D, substrate isolation structure 125, and the gate structure (e.g., gate stack 130 and gate spacers 145). Dielectric layer 150 may have a multilayer structure, such as a contact etch stop layer (CESL) 152 and an interlayer dielectric (ILD) layer 154. ILD layer 154 is disposed over CESL 152. ILD layer 154 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or combinations thereof. In some embodiments, ILD layer 154 includes a dielectric material having a dielectric constant that is less than a dielectric constant of silicon dioxide (e.g., k<3.9). In some embodiments, ILD layer 154 includes a dielectric material having a dielectric constant that is less than about 2.5, such as porous silicon oxide, silicon carbide, carbon-doped oxide (e.g., SiCOH-based material), or combinations thereof. CESL 152 includes a dielectric material that is different than the dielectric material of ILD layer 154. For example, where ILD layer 154 includes silicon and oxygen (e.g., porous silicon oxide), CESL 152 may include silicon and nitrogen, and CESL 154 may be a silicon nitride layer, a silicon carbonitride layer, or a silicon oxycarbonitride layer.

In TFET 100, profiles and compositions of the gate structure (e.g., gate stack 130, source-side gate dielectric 134, drain-side gate dielectric 136, gate electrode 140, or combinations thereof), source 120S, and drain 120D are tuned and/or configured to provide an asymmetric electric field along channel 110C that may increase source-side gate control and reduce gate-induced drain leakage (GIDL), thereby maximizing BTBT source-channel tunneling while minimizing BTBT drain-channel tunneling. For example, referring to FIG. 2B, profiles and compositions of the gate structure, source 120S, and drain 120D provide TFET 100 with a graded electric field along channel 110C that decreases from source 120S to drain 120D. The graded electric field may have maximum strength near and/or adjacent to source 120S and minimum strength near and/or adjacent to drain 120D, which increases source-channel junction sensitivity to voltage applied to the gate structure (e.g., to gate electrode 140), decreases drain-channel junction sensitivity to the applied gate voltage, reduces and/or minimizes off-state leakage current at the drain-channel junction, or combinations thereof. Increasing source-channel junction sensitivity to the applied gate voltage may enable operation of TFET 100 at lower threshold voltages, thereby facilitating low power operation needed for scaled devices. As described further, a profile of the gate structure and a profile of source 120S may be configured to provide gate-source overlap that increases a source-side electric field along channel 110C, a profile of the gate structure and a profile of drain 120D may be configured to provide gate-drain underlap that decreases a drain-side electric field along channel 110C, and compositions and/or thicknesses of source-side gate dielectric 134 and drain-side gate dielectric 136 may be configured to increase the source-side electric field along channel 110C and decrease the drain-side electric field along channel 110C, thereby improving performance of TFET 100.

Referring to FIG. 1, FIG. 2A, FIG. 3, FIG. 4, and FIG. 7, gate stack 130 has a gate width (also referred to as a gate critical dimension (CD)) along the lengthwise direction of fin 110 (e.g., along the x-direction). Because of processing limitations, such as an etching process's limited ability to provide high aspect ratio gate patterns with substantially vertical sidewalls, lower, bottom portions of gate stack 130 that intersect fin 110 may be wider than upper, top portions of gate stack 130. For example, a top gate portion GT of gate stack 130 has a width W_{T} and a bottom gate portion GB of gate stack 130 has a width W_{B} that is greater than width W_{T}. In the depicted embodiment, top gate portion GT has substantially vertical sidewalls, such that width W_{T} is substantially the same along a height of gate stack 130 (i.e., width W_{T} is uniform from a top to a bottom of top gate portion GT), and bottom gate portion GB has tapered sidewalls, such that width W_{B} increases along the height of gate stack 130 (i.e., width W_{B} increases from a top to a bottom of bottom gate portion GB). Gate stack 130 may thus have different gate widths (i.e., gate CDs) when measured at different locations of gate stack 130 along its height. In the depicted embodiment, top gate portion GT is between a top of gate stack 130 to a top of fin 110 (or slightly below the top of fin 110), which is designated as fin top FT, and bottom gate portion GB is between fin top FT (or slightly below fin top FT) to substrate isolation structure 125. In some embodiments, top gate portion GT may be between the top of gate stack 130 to a distance below fin top FT, and bottom gate portion GB may be between the distance below fin top FT to substrate isolation structure 125. In other words, gate stack 130 may have width W_{T} from a top thereof to the distance below fin top FT, and gate stack 130 may have width W_{B} from the distance below fin top FT to substrate isolation structure 125.

Portions of bottom gate portion GB that provide widening of gate stack 130 are referred to as gate footing. In MOS transistors, since larger gate CDs lead to greater saturation current (Iₛₐₜ) and threshold voltage (Vₜ), gate footing is often viewed as detrimental to transistor performance and thus gate fabrication and gate profiles are typically designed to limit gate footing and/or reduce any overlap of gate footing and source/drains. In contrast, the present disclosure recognizes that, in TFETs, gate footing may be utilized to provide gate-source overlap that enlarges and/or improves source-side gate control and/or gate-drain underlap that reduces drain-side ambipolar leakage. TFET 100 may thus utilize gate footing to provide gate-source overlap and/or gate-drain underlap that optimizes its performance. For example, fabrication of the gate structure (e.g., of a dummy gate thereof, which is subsequently replaced with gate dielectric 132 and gate electrode 140, as described below) is tuned and/or configured to provide gate stack 130 with a source-side gate footing GFS and a drain-side gate footing GFD that may increase gate-source overlap and gate-drain underlap, respectively, which may increase tunneling at the source-channel junction while reducing tunneling at the drain-channel junction.

Referring to FIG. 2A, FIG. 4, and FIG. 7, source-side gate footing GFS provides gate-source overlap along both the x-direction and the y-direction, which increases an electric field along channel 110C adjacent to and/or near source 120S, thereby increasing tunneling probability at the source-channel junction and thus increasing tunneling current of TFET 100. For example, referring to FIG. 9, TFET 100 may have three source-channel tunneling paths, such as a top vertical tunneling path along and/or in a top of fin 110, a lateral tunneling path along and/or in a middle of fin 110, and a bottom vertical tunneling path along and/or in a bottom of fin 110. Using source-side gate footing GFS to increase overlap between gate stack 130 and source 120S may increase vertical tunneling of TFET 100. Referring to FIG. 2A and FIG. 4, both source-side gate dielectric 134 and gate electrode 140 form source-side gate footing GFS, such that source-side gate dielectric 134 and gate electrode 140 overlap source 120S along the y-direction. Source-side gate footing GFS has a width G_{FX} along the lengthwise direction of fin 110 (e.g., along the x-direction), and width G_{FX} corresponds with a portion of gate stack 130 in an isolation region of TFET 100 that overlaps source 120S, for example, along the y-direction. In some embodiments, width G_{FX} is less than about 30% of width W_{T} (i.e., 0.3W_{T}≥G_{FX}≥0). Referring to FIG. 2A, FIG. 4, and FIG. 7, a length of gate-source overlap (L_{S-overlap}) is provided by source-side gate footing GFS. L_{S-overlap} corresponds with a length of gate electrode 140 along the x-direction that overlaps source 120S along the y-direction. In some embodiments, since width G_{FX} of source-side gate footing GFS may increase from top to bottom, L_{S-overlap} may increase from a top to a bottom of source-side gate footing GFS and/or bottom gate portion GB. In some embodiments, since a profile of source 120S may vary, L_{S-overlap} may vary depending on the profile of source 120S and width G_{FX} at a given location of gate stack 130.

A profile of source 120S may also be tuned to provide the desired gate-source overlap. For example, source 120S has bowed sidewalls (FIG. 3 and FIG. 4), which increases a width of source 120S along the lengthwise direction of fin 110, so that source 120S laterally extends under source-side gate spacer 145S. Source 120S extends (e.g., along the x-direction) a distance Sₚᵤₛₕ beyond source-side gate spacer 145S, such that source 120S extends under gate stack 130. In the depicted embodiment, distance Sₚᵤₛₕ is greater than a thickness t1 of source-side gate dielectric 134, and source 120S extends laterally beyond source-side gate dielectric 134. In other words, in the active region, source 120S extends under source-side gate spacer 145S, source-side gate dielectric layer 134, and gate electrode 140. Distance Sₚᵤₛₕ corresponds with gate-source overlap in an active region of TFET 100, and distance Sₚᵤₛₕ is between an inner sidewall of source-side gate spacer 145S, which is adjacent to source-side gate dielectric layer 134, and a gate-side tip/edge T of source 120S, which corresponds with a furthest channel-facing/extending portion of source 120S. In the depicted embodiment, gate-side tip/edge T corresponds with the widest/longest portion of source 120S (i.e., a portion of source 120S having a maximum width/length) along the lengthwise direction of fin 110, which may be a middle portion of source 120S, such as where source 120S is provided with bowed sidewalls, such as depicted. In some embodiments, source-side gate spacer 145S has a spacer thickness S along the lengthwise direction of fin 110 (e.g., along the x-direction), and distance Sₚᵤₛₕ is greater than about zero and less than about 60% of spacer thickness S (i.e., 0.6S≥ₚᵤₛₕ≥0).

In some embodiments, at fin top FT, source 120S laterally extends under source-side gate spacer 145S, such as depicted. In such embodiments, a distance Sₘᵢₙ is between source 120S at fin top FT and the inner sidewall of source-side gate spacer 145S. Distance Sₘᵢₙ is greater than zero and less than about 90% of spacer thickness S (i.e., 0.9S≥Sₘᵢₙ>0). In other words, at fin top FT, source 120S does not extend under and/or touch inner sidewall of source-side gate spacer 145S, but source 120S may extend under and physically contact a thickness of source-side gate spacer 145S that is less than about 10% of spacer thickness S.

Using source-side gate footing GFS to increase gate-source overlap (e.g., along the y-direction and the x-direction) and enlarging a profile of source 120S to increase gate-source overlap (e.g., along the z-direction and the x-direction, for example, by pushing source 120S closer to a gate region (e.g., gate electrode 140 thereof)) increases a strength of an electric field adjacent to source 120S. TFET 100 is thus provided with a strong source-side electric field along channel 110C (see, e.g., FIG. 2B), which increases source-channel junction sensitivity to voltage applied to the gate structure (e.g., to gate electrode 140) and thus source-side gate control, thereby maximizing source-channel BTBT tunneling of TFET 100.

Referring to FIG. 2A, FIG. 4, and FIG. 7, drain-side gate footing GFD provides gate-drain underlap along both the x-direction and the y-direction, which decreases an electric field along channel 110C adjacent to and/or near drain 120D, thereby decreasing ambipolar effects and/or ambipolar conduction at the drain-channel junction and thus decreasing GIDL. Referring to FIG. 2A and FIG. 4, in contrast to source-side gate footing GFS, which is formed from gate electrode 140 and source-side gate dielectric layer 134, drain-side gate footing GFD is formed from drain-side gate dielectric layer 136, but not gate electrode 140. Because drain-side gate footing GFD does not include gate electrode 140, gate electrode 140 does not overlap drain 120D along the y-direction, even as the width of gate stack 130 increases along its height. Instead, drain-side gate dielectric layer 136 and/or drain-side gate spacer 145D overlap drain 120D along the y-direction. Drain-side gate dielectric layer 136 has a thickness t2 in top gate portion GT and a thickness t3 in bottom gate portion GB. In the depicted embodiment, because drain-side gate dielectric layer 136 fills drain-side gate footing GFD, thickness t3 may be a sum thickness t2 and width G_{FX}. Thickness t3 corresponds with a portion of gate stack 130 in an isolation region of TFET 100 (here, a portion of drain-side gate dielectric layer 136) that may separate gate electrode 140 (e.g., a sidewall thereof) from drain 120S (e.g., along the x-direction) and/or provide underlap therebetween. In some embodiments, thickness t3 is less than about 60% of width W_{T} (i.e., 0.6W_{T}≥t3>0). In some embodiments, in a top view (FIG. 2A), a distance D is between gate electrode 140 (e.g., a drain-side sidewall thereof) and drain 120D (e.g., a tip/edge thereof), and distance D is greater than or equal to thickness t3 (e.g., D≥t3). Increasing distance D and/or thickness t3 (and thus increasing a thickness of drain-side gate dielectric layer 136) reduces an electric field near drain 120D and/or increases a band gap of channel-to-drain material (thus decreases tunneling probability), which reduces ambipolar effects.

Referring to FIG. 2A, FIG. 4, and FIG. 7, a length of gate-drain underlap (LD-underlap) is provided by drain-side gate dielectric layer 136 and/or drain-side gate footing GFS. LD-underlap corresponds with a distance along the x-direction that gate electrode 140 underlaps drain 120D along the y-direction. Put another way, LD-underlap is a distance between gate electrode 140 (e.g., a drain-side sidewall thereof) and drain 120D (e.g., a tip/edge thereof). In some embodiments, since width G_{FX} of drain-side gate footing GFD may increase from top to bottom and a profile of drain 120D may vary along its depth, LD-underlap may vary depending on the profile of drain 120D and width G_{FX} at a given location of gate stack 130. Forming drain-side gate footing GFD from drain-side gate dielectric layer 136 may maintain gate-drain underlap even as a width of bottom gate portion GB increases from top to bottom. In some embodiments, such as depicted, gate-drain underlap may be maintained along an entire height of gate stack 130.

A profile of drain 120D may also be tuned to provide the desired gate-drain underlap. For example, drain 120D has tapered sidewalls (FIG. 3 and FIG. 4), such that drain 120D has a width that decreases along the lengthwise direction of fin 110 from top to bottom and drain 120D laterally extends and/or pulls away from gate stack 130 and/or drain-side gate spacer 145D. A distance dᵤ corresponds with gate-drain underlap in an active region of TFET 100, and distance dᵤ is between a drain-side sidewall of gate electrode 140, which is adjacent to drain-side gate dielectric layer 136, and a gate-side sidewall of drain 120D. In the depicted embodiment, because drain 120D has tapered sidewalls, distance dᵤ increases along a depth of drain 120D, such as from fin top FT to a depth of drain 120D in fin 110. To ensure sufficient gate-drain underlap, distance dᵤ may be at least thickness t2 (i.e., dᵤ≥t2). In the depicted embodiment, drain-side spacer 145D also has spacer thickness S, and at fin top FT, distance dᵤ is greater than thickness t2 and less than a sum of thickness t2 and spacer thickness S (i.e., (S+t2)>dᵤ>t2). As depth of drain 120D increases, distance dᵤ increases and distance dᵤ may be greater than or equal to a sum of thickness t2 and spacer thickness S (i.e., dᵤ≥(S+t2)).

Using drain-side gate footing GFD to increase gate-drain underlap (e.g., along the y-direction and the x-direction) and reducing a profile of drain 120D to increase gate-drain underlap (e.g., along the z-direction and the x-direction, for example, by pulling drain 120D away from a gate region (e.g., gate electrode 140 thereof)) decreases a strength of an electric field adjacent to drain 120D. TFET 100 is thus provided with a weak drain-side electric field along channel 110C (see, e.g., FIG. 2B), which decreases drain-channel junction sensitivity to voltage applied to the gate structure (e.g., to gate electrode 140) and thus drain-side gate control, thereby minimizing drain-channel BTBT tunneling of TFET 100.

Asymmetric gate dielectric 132 further contributes to the asymmetric electric field along channel 110C. For example, since increasing a dielectric constant of gate dielectric 132 increases an electric field along channel 110C, configuring gate dielectric 132 with source-side gate dielectric layer 134 having a dielectric constant that is greater than a dielectric constant of drain-side gate dielectric layer 136 increases the source-side electric field relative to the drain-side electric field, thereby increasing sensitivity of the source-channel junction to a voltage applied to the gate structure (e.g., to gate electrode 140) relative to sensitivity of the drain-channel junction to the applied voltage. In the depicted embodiment, source-side gate dielectric layer 134 and drain-side gate dielectric layer 136 have substantially the same thickness (e.g., t1≈t2). In such embodiments, gate electrode 140 may be symmetric along midline M in top gate portion GT (e.g., a source-side portion of gate electrode 140 may have a width w1 that is substantially equal to a width w2 of a drain-side portion of gate electrode 140 (i.e., w1≈w2), but gate electrode 140 may be asymmetric along midline M in bottom gate portion GB (e.g., width w1 of source-side portion of gate electrode 140 increases from top to bottom of bottom gate portion GB, while width w2 of drain-side portion of gate electrode 140 is substantially the same from top to bottom of bottom gate portion GB). Further, in the depicted embodiment, a length l1 of source-side gate dielectric 134 along channel 110C is greater than a length l2 of drain-side gate dielectric 134 along channel 110C (i.e., l1>l2). In some embodiments, length l1 is substantially the same as length l2 (i.e., l1≈l2). In some embodiments length l1 is less than length l2 (i.e., l1<l2), which may further reduce the drain-side electric field and/or sensitivity of the drain-channel junction to a voltage applied to the gate structure (e.g., gate electrode 140 thereof). In some embodiments, thickness t1 is at least 0.8 nm (i.e., t1≥0.8 nm). In some embodiments, thickness t2 of drain-side gate dielectric layer 136 may be increased to further reduce the drain-side electric field, such as depicted in FIG. 10 and FIG. 11. Increasing thickness t2 increases a distance between gate electrode 140 and drain 120D. In such embodiments, thickness t2 is greater than thickness t1, and gate electrode 140 may be asymmetric along midline M in top gate portion GT (e.g., width w1 of the source-side portion of gate electrode 140 is greater than width w2 of the drain-side portion of gate electrode 140 (i.e., w1>w2). Further, in such embodiments, a width of gate electrode 140 is reduced.

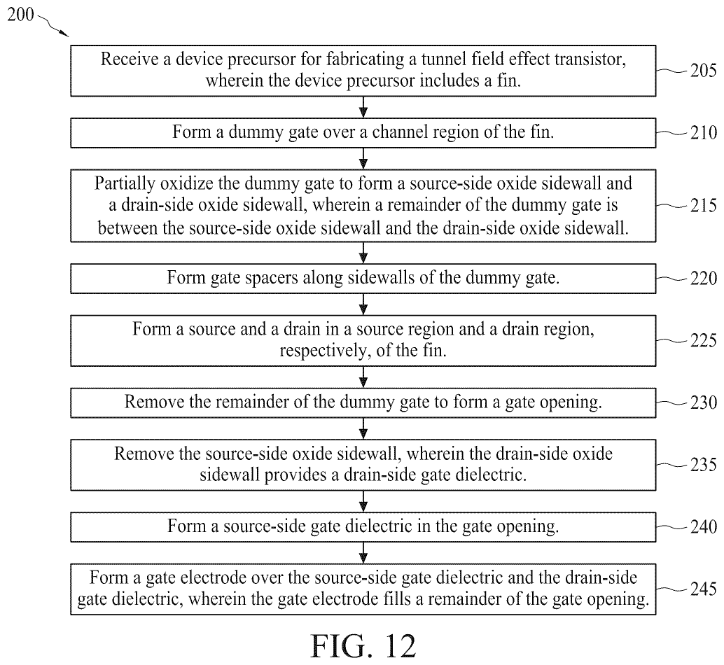

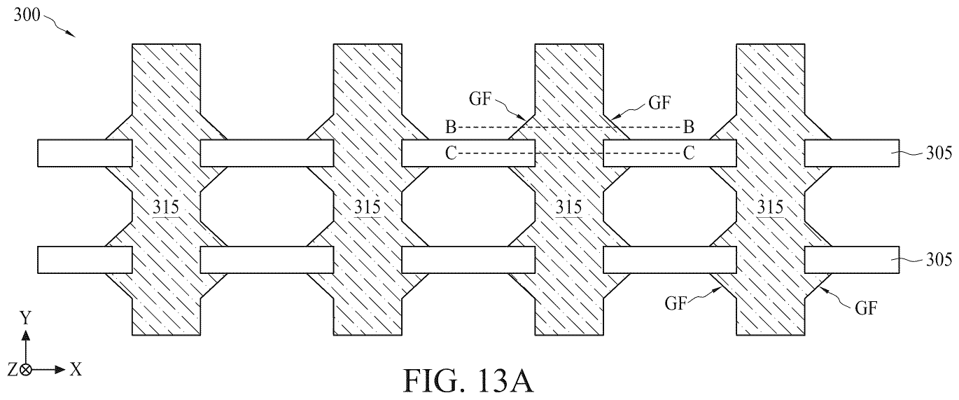

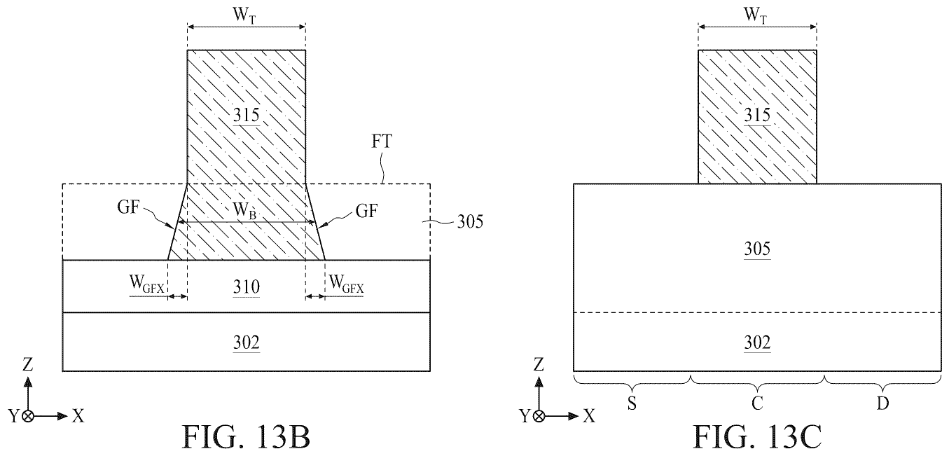

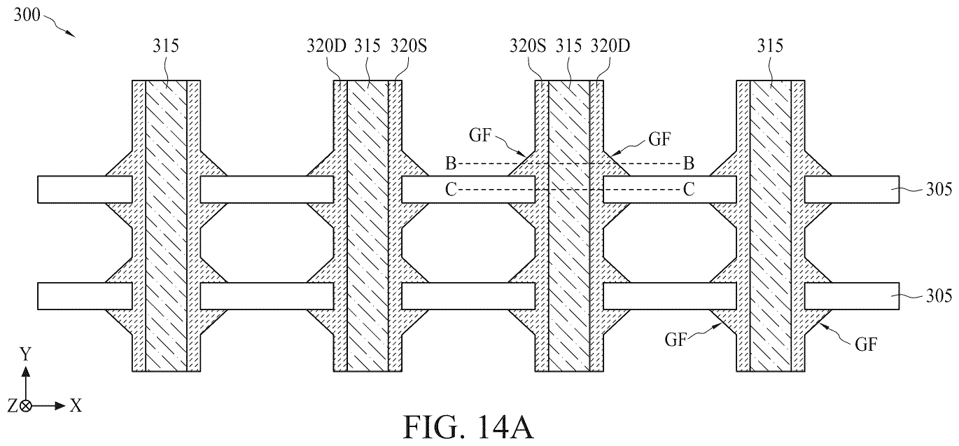

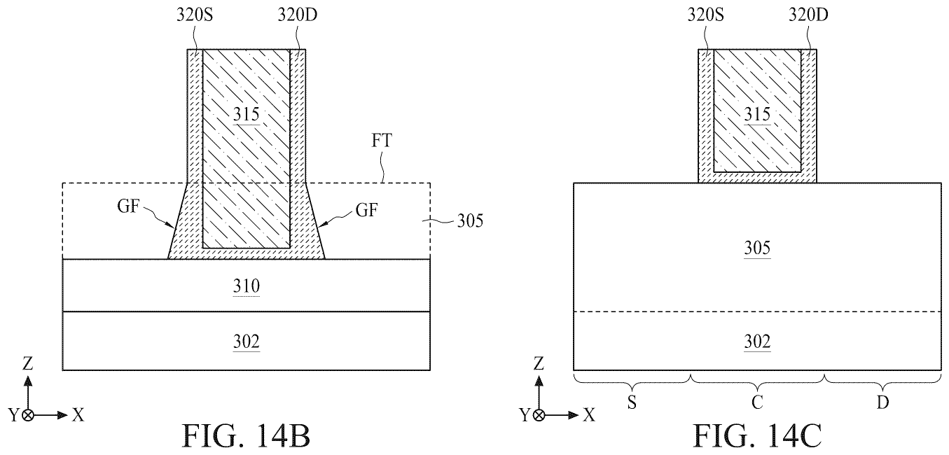

FIG. 12 is a flow chart of a method 200 for fabricating a tunnel field effect transistor (TFET), in portion or entirety, according to various aspects of the present disclosure. FIGS. 13A-23A are top views of a device 300, in portion or entirety, at various fabrication stages of method 200 of FIG. 12, according to various aspects of the present disclosure. FIGS. 13B-23B are cross-sectional views of device 300 along line A-A of FIGS. 13A-23A, respectively, and FIGS. 13C-23C are cross-sectional views of device 300 along line B-B of FIGS. 13A-23A, respectively, according to various aspects of the present disclosure. Method 200 may fabricate TFETs of device 300 that may be similar to TFET 100. For ease of description and understanding, FIG. 12, FIGS. 13A-23A, FIGS. 13B-23B, and FIGS. 13C-23C are discussed concurrently. FIG. 12, FIGS. 13A-23A, FIGS. 13B-23B, and FIGS. 13C-23C have been simplified for the sake of clarity to better understand the inventive concepts of the present disclosure. Additional steps may be provided before, during, and after method 200, and some of the steps described may be moved, replaced, or eliminated for additional embodiments of method 200. Additional features may be added in device 300, and some of the features described below may be replaced, modified, or eliminated in other embodiments of device 300.

Referring to FIG. 12 and FIGS. 13A-13C, method 200 at block 205 includes receiving a device precursor for fabricating a TFET. In the depicted embodiment, the device precursor includes a substrate 302, fins 305 extending from substrate 302, and substrate isolation structures 310 disposed over substrate 302. Substrate 302 may be similar to substrate 102 described above, fins 305 may be similar to fin 110 described above, and substrate isolation structures 310 may be similar to substrate isolation structures 125 described above.

Referring to FIG. 12 and FIGS. 13A-13C, method 200 at block 210 includes forming a dummy gate over a channel region of the fin. In FIGS. 13A-13C, dummy gates 305 are formed over channel regions of fins 305. Dummy gates 315 extend lengthwise in a direction that is different than (e.g., orthogonal to) the lengthwise direction of fins 305. For example, fins 305 extend lengthwise along the x-direction, and dummy gates 315 extend lengthwise along the y-direction. A respective dummy gate 315 is disposed over channel regions (C) and between source regions(S) and drain regions (D) of fins 305. In active regions of device 300, dummy gates 315 may be disposed on tops and sidewalls of fins 305, and dummy gates 315 may wrap channel regions of fins 305. In isolation regions of device 300, dummy gates 315 may be disposed over tops of substrate isolation structures 310. In FIG. 13C (e.g., an active region), a respective dummy gate 315 is disposed over a top of a channel region of a respective fin 305 and is further disposed between a source region and a drain region of the respective fin 305.

Dummy gates 315 include a dummy material that may be oxidized during subsequent processing to form oxide layers having a composition that reduces sensitivity of the channel regions of fins 305 to gate control. In the depicted embodiment, the dummy material is a silicon-comprising material, such as polysilicon, and dummy gates 315 may be referred to as poly gates. Each dummy gate 315 may include a single layer (e.g., one polysilicon layer) or multiple layers, such as a dummy gate dielectric (e.g., a silicon oxide layer), a dummy gate electrode (e.g., a polysilicon layer), a hard mask, other suitable layers, or combinations thereof.

Dummy gates 315 are formed by deposition processes, lithography processes, etching processes, other suitable processes, or combinations thereof. For example, forming dummy gates 315 may include depositing a polysilicon layer over device 300, forming an etch mask over the polysilicon layer (e.g., performing a lithography process to form a patterned hard mask and/or a patterned resist thereover), and etching the polysilicon layer using the etch mask. Remainders of the polysilicon layer form dummy gates 315 over fins 305, such as depicted. The polysilicon layer may be deposited by chemical vapor deposition (CVD), physical vapor deposition (PVD), atomic layer deposition (ALD), other deposition process, or combinations thereof.

Dummy gates 315 are fabricated by a process that accounts for and is tuned based on a target gate CD (e.g., width W_{T} and/or width W_{B}), a target gate-source overlap, a target gate-drain underlap, other target parameters (e.g., target gate-source relationship parameters, target gate-drain relationship parameters, target gate parameters, etc.), or combinations thereof. In the depicted embodiment, dummy gates 315 are intentionally fabricated to have gate footing GF that increases gate-source overlap and/or increases gate-drain underlap, which may improve TFET performance as described herein. Parameters of the dummy gate fabrication process (e.g., etch parameters, such as etchant, etch time, etch direction, etch type, etc.) may be tuned to provide dummy gates 315 with sidewall profiles that provide target gate CD (e.g., substantially vertical sidewalls above fin top FT and tapered sidewalls below fin top FT) and/or provide gate footing GF with a target gate foot width (e.g., width W_{GFX}) and/or a target sidewall tapering. In some embodiments, parameters of the dummy gate fabrication process are tuned to provide gate footing GF at a target location relative to fin top FT of fins 305 (e.g., from about fin top FT to substrate isolation structures 310, such as depicted, or from a distance below fin top FT to substrate isolation structures 310, in some embodiments). The target gate foot width, the target sidewall tapering, the target location, or combinations thereof may account for source profile and drain profile to maximize gate-source overlap and gate-drain underlap, respectively.

Referring to FIG. 12 and FIGS. 13A-13C, method 200 at block 215 includes partially oxidizing the dummy gate to form a source-side oxide sidewall and a drain-side oxide sidewall, where a remainder of the dummy gate is between the source-side oxide sidewall and the drain-side oxide sidewall. In FIGS. 13A-13C, an oxidation process is performed to partially oxidize dummy gates 315 to form source-side oxide sidewalls 320S, which are adjacent to the source regions of fins 305, and drain-side oxide sidewalls 320D, which are adjacent to drain regions of fins 305. In other words, portions of dummy gates 315 (e.g., poly gates) are converted into oxide portions/layers (e.g., polysilicon oxide portions/layers). After the oxidation process, a remainder of each dummy gate 315 is disposed between a respective source-side oxide sidewall 320S and a respective drain-side oxide sidewall 320D. Source-side oxide sidewalls 320S and drain-side oxide sidewalls 320D may include silicon and oxygen, and dummy gates 315 may include polysilicon. Source-side oxide sidewalls 320S and drain-side oxide sidewalls 320D may further include nitrogen, and in some embodiments, may further include carbon. For example, source-side oxide sidewalls 320S and drain-side oxide sidewalls 320D may be SiOₓN layers.

The oxidation process accounts for and is tuned based on a target gate-drain underlap and/or other target gate-drain relationship parameters (e.g., thickness t2, thickness t3, a target distance between a gate electrode of a gate stack and a gate-facing tip/edge of a drain, etc.). For example, the oxidation process is tuned to completely oxidize portions of dummy gates 315 that form gate footing GF, such that gate footing GF is formed by oxide, but not dummy gates 315, after the oxidation process (i.e., a thickness of source-side oxide sidewalls 320S and drain-side oxide sidewalls 320D in a bottom portion of the gate structure (e.g., below fin top FT) is at least W_{GFX}). Further, the oxidation process may be continued until drain-side oxide sidewalls 320D have a desired thickness in a top portion of the gate structure (i.e., above fin top FT), which may be a target thickness of drain-side gate dielectrics of TFETs of device 300.

In some embodiments, the oxidation process is a thermal oxidation process. In such embodiments, source-side oxide sidewalls 320S and drain-side oxide sidewalls 320D may be formed by thermal oxidation of polysilicon. In some embodiments, the thermal oxidation process is conducted in oxygen ambient. In some embodiments, the thermal oxidation process is conducted in nitrogen ambient and/or carbon ambient. In some embodiments, parameters of the oxidation process may be tuned to oxidize outer portions of dummy gates 315, but not inner portions of dummy gates 315, thereby forming outer oxide layers. Each of the outer oxide layers may be form a respective source-side oxide sidewall 320S and a respective drain-side oxide sidewall 320D. In some embodiments, each of the outer oxide layers may further include a bottom portion that extends from the respective source-side oxide sidewall 320S to the respective drain-side oxide sidewall 320D. In such embodiments, the outer oxide layers may wrap inner portions of dummy gates 315 (i.e., remaining, unoxidized portions of dummy gates 315), such as depicted. In some embodiments, bottoms of dummy gates 315 are not oxidized by the oxidation process and oxide layers are not between bottoms of dummy gates 315 and fin tops FT of fins 305 and/or between bottoms of dummy gates 315 and substrate isolation structures 310. Parameters of the oxidation process that may be tuned to achieve desired oxidation include time, temperature, ambient, pressure, other parameters, or combinations thereof.

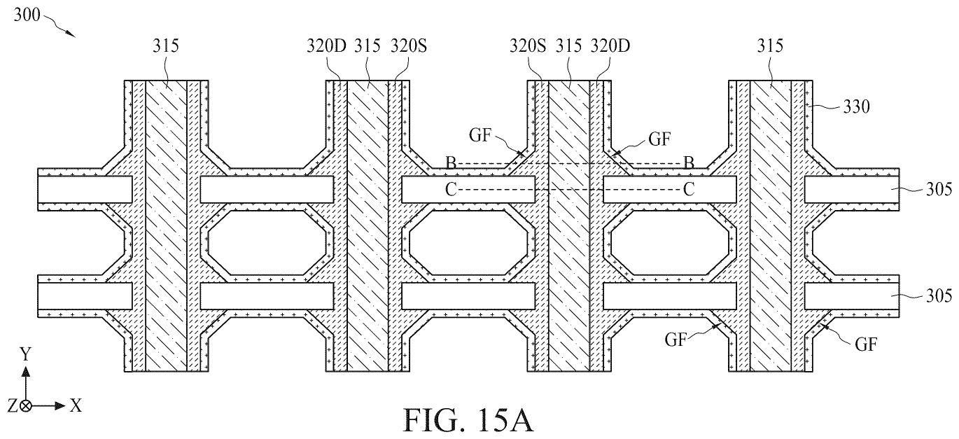

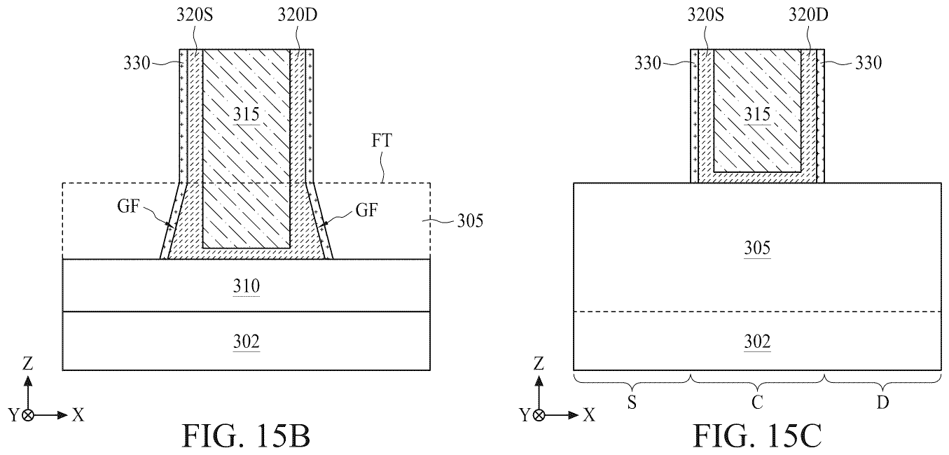

Referring to FIG. 12 and FIGS. 15A-15C, method 200 at block 220 includes forming gate spacers along sidewalls of the dummy gate. In FIGS. 15A-15C, gate spacers 330 are formed along sidewalls of dummy gates 315, thereby forming gate structures. In the depicted embodiment, because dummy gates 315 are partially oxidized before forming gate spacers 330, gate spacers 330 are disposed along source-side oxide sidewalls 320S and drain-side oxide sidewalls 320D, such that source-side oxide sidewalls 320S are between dummy gates 315 and gate spacers 330 and drain-side oxide sidewalls 320D are between dummy gates 315 and gate spacers 330. A gate structure may collectively refer to a respective dummy gate 315 and gate spacers 330 disposed along sidewalls thereof, and in the depicted embodiment, may further refer to a respective source-side oxide sidewall 320S and a respective drain-side oxide sidewall 320D. Gate spacers 330 may be similar to gate spacers 145 described above. For example, gate spacers 330 include a dielectric material that includes silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, forming gate spacers 330 includes depositing a spacer layer that includes silicon and nitrogen and/or carbon (e.g., an SiN layer, an SiC layer, or an SiCN layer) over device 300 and etching the spacer layer. In some embodiments, source-side oxide sidewalls 320S and drain-side oxide sidewalls 320D may be referred to as first gate spacers, and gate spacers 330 may be referred to as second gate spacers. In other words, first gate spacers may be formed along sidewalls of dummy gates 315 by partially oxidizing dummy gates 315 and second gate spacers may be formed along sidewalls of dummy gates 315 and adjacent to the first gate spacers by a deposition process and an etching process.

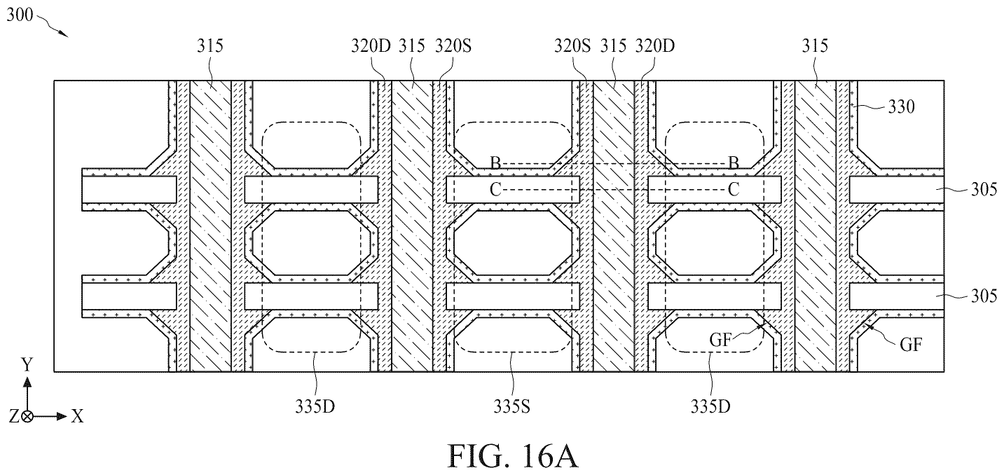

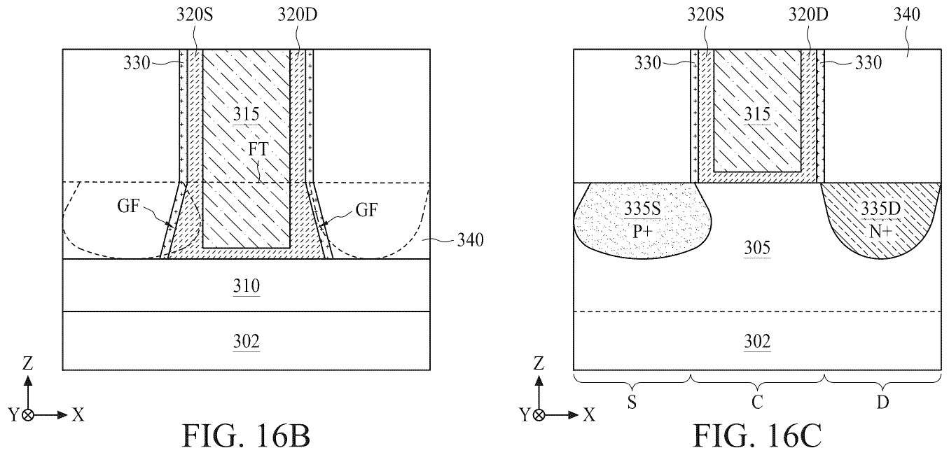

Referring to FIG. 12 and FIGS. 16A-16C, method 200 at block 225 includes forming a source and a drain in a source region and a drain region, respectively, of the fin. In FIGS. 16A-16C, sources 335S are formed in source regions of fins 305, and drains 335D are formed in drain regions of fins 305. Sources 335S and drains 335D may be similar to source 120S and drain 120D, respectively, described above. For example, sources 335S have a first conductivity type, drains 335D have a second conductivity type that is opposite the first conductivity type, sources 335S have a source profile that optimizes gate-source overlap, and drains 335D have a drain profile that optimizes gate-drain underlap, such as described herein.

Forming sources 335S and drains 335D may include forming source recesses (e.g., having bowed sidewalls) in source regions of fins 305, forming drain recesses (e.g., having tapered sidewalls) in drain regions of fins 305, forming a first semiconductor material having the first conductivity type that fills the source recesses, and forming a second semiconductor material having the second conductivity type that fills the drain recesses. In some embodiments, the first semiconductor material and the second semiconductor material have the same compositions but different conductivities. In some embodiments, the first semiconductor material and the second semiconductor material have different compositions and different conductivities. In some embodiments, sources 335S and drains 335D are formed in separate processing sequences. For example, source regions are masked when forming drains 335D, and drain regions are masked when forming sources 335S. In some embodiments, sources 335S and drains 335D are formed at least partially simultaneously. For example, a same epitaxial growth process may be used to form a semiconductor material of sources 335S and drains 335D.

In some embodiments, the first semiconductor material and/or the second semiconductor material is formed by an epitaxy process, which may use chemical vapor deposition (CVD) deposition techniques (e.g., remote plasma CVD (RPCVD), low pressure CVD (LPCVD), vapor phase epitaxy (VPE), ultra-high vacuum CVD (UHV-CVD), or combinations thereof), molecular beam epitaxy (MBE), other suitable epitaxial growth processes, or combinations thereof. In such embodiments, sources 335S and drains 335D may be referred to as epitaxial sources and epitaxial drains, respectively. The epitaxy process may use gaseous precursors and/or liquid precursors, which interact with the compositions of fins 305. In some embodiments, the first semiconductor material and/or the second semiconductor material is doped during deposition by adding impurities to a source material of the epitaxy process (i.e., in-situ). In some embodiments, the first semiconductor material and/or the second semiconductor material are doped by an ion implantation process or other doping process after the epitaxy process and/or other deposition process. In some embodiments, annealing processes (e.g., rapid thermal annealing and/or laser annealing) are performed to activate dopants in the first semiconductor material and/or the second semiconductor material.

In some embodiments, a dielectric layer 340 is formed over device 300 after forming the source, such as sources 335S, and the drain, such as drains 335D. Dielectric layer 340 may be similar to dielectric layer 150 described above. For example, dielectric layer 340 may include a CESL, such as CESL 152, and an ILD layer, such as ILD layer 154. In some embodiments, forming dielectric layer 340 includes depositing the CESL over device 300, depositing the ILD layer over the CESL, and performing a planarization process. The planarization process may remove any of the CESL and/or ILD layer over a top of dummy gates 315. In some embodiments, the planarization process stops upon reaching dummy gates 315.

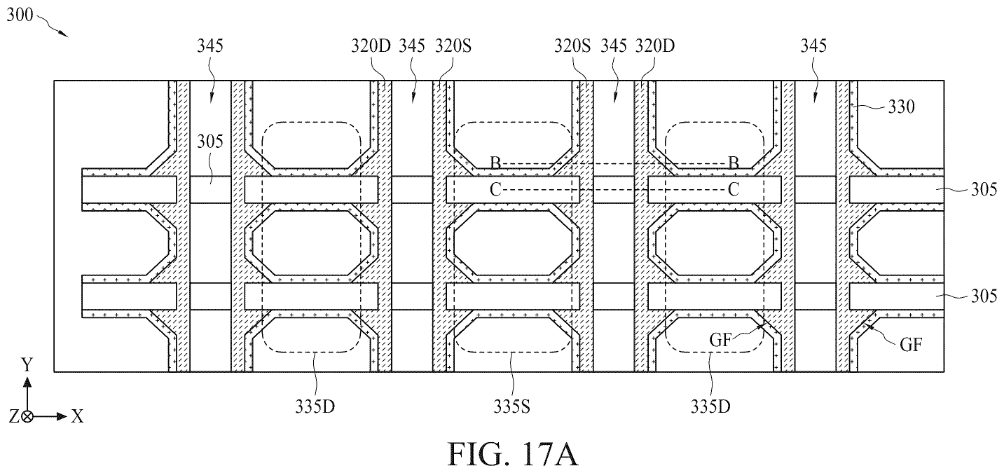

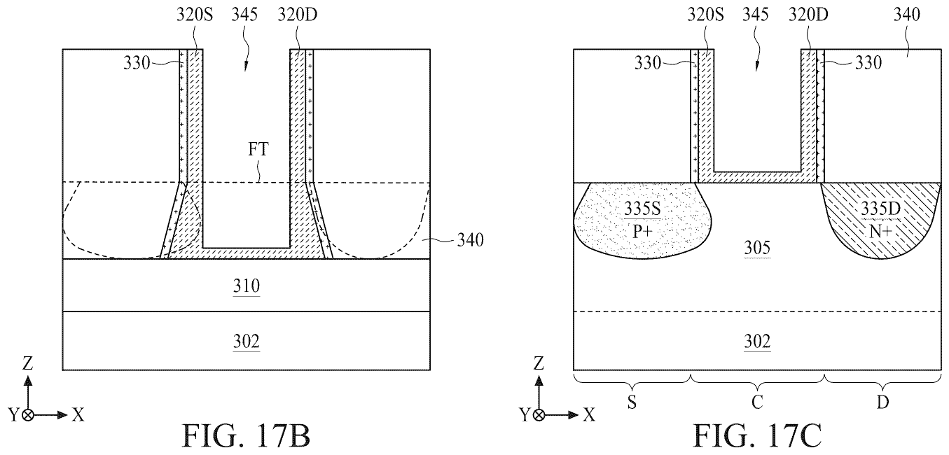

Referring to FIG. 12 and FIGS. 17A-17C, method 200 at block 230 includes removing the remainder of the dummy gate to form a gate opening. In FIGS. 17A-17C, remainders of dummy gates 315 are removed to form gate openings 345. In some embodiments, an etching process selectively removes dummy gates 315 with respect to oxide sidewalls (e.g., source-side oxide sidewalls 320S and drain-side oxide sidewalls 320D). For example, the etching process etches dummy gates 315 with no (or negligible) etching of source-side oxide sidewalls 320S and drain-side oxide sidewalls 320D. An etchant of the etching process may etch polysilicon (i.e., dummy gates 315) at a higher rate than oxide (i.e., source-side oxide sidewalls 320S and drain-side oxide sidewalls 320D). The etching process is a dry etch, a wet etch, other suitable etch, or combinations thereof. In some embodiments, a patterned mask layer covers dielectric layer 340 and/or gate spacers 330 and exposes dummy gates 315 during the etching process. In some embodiments, the etching process may also selectively remove dummy gates 315 with respect to gate spacers 330, dielectric layer 340, or combinations thereof. For example, the etching process may etch dummy gates 315 with no (or negligible) etching of the oxide sidewalls, gate spacers 330, and dielectric layer 340. In such example, an etchant of the etching process may etch polysilicon (i.e., dummy gates 315) at a higher rate than dielectric materials.

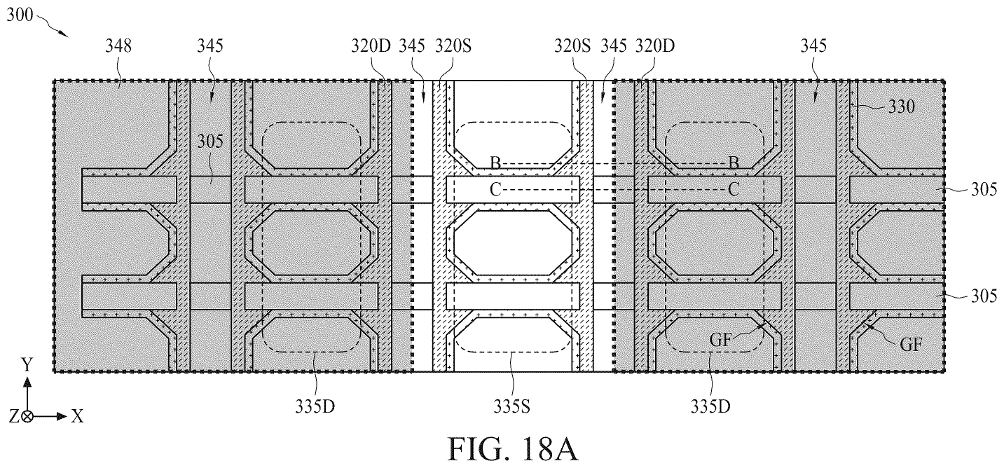

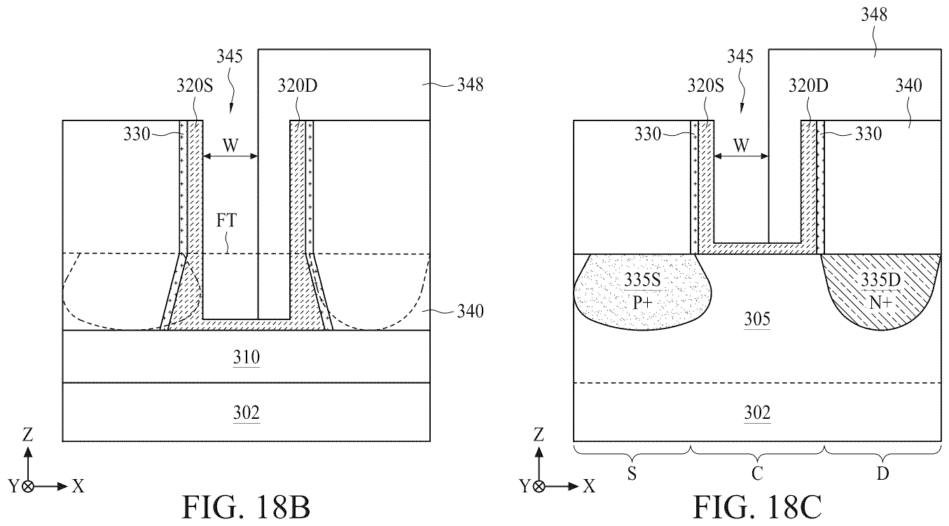

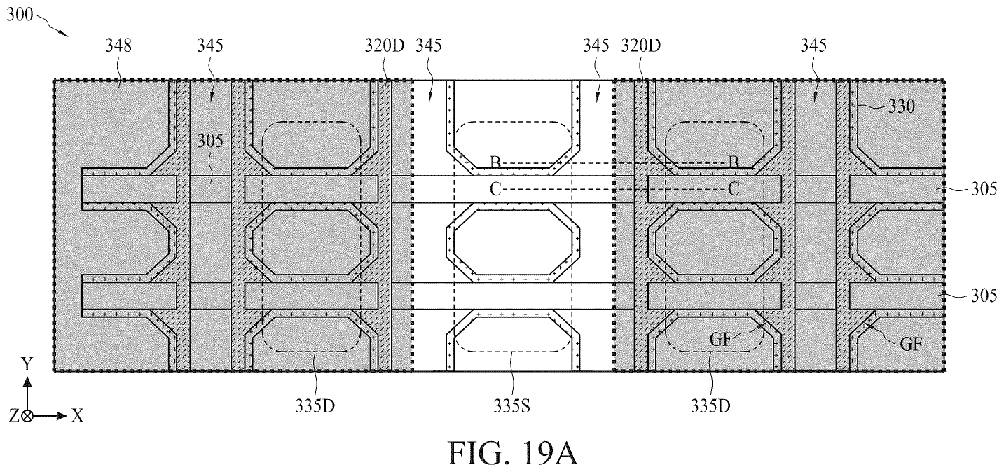

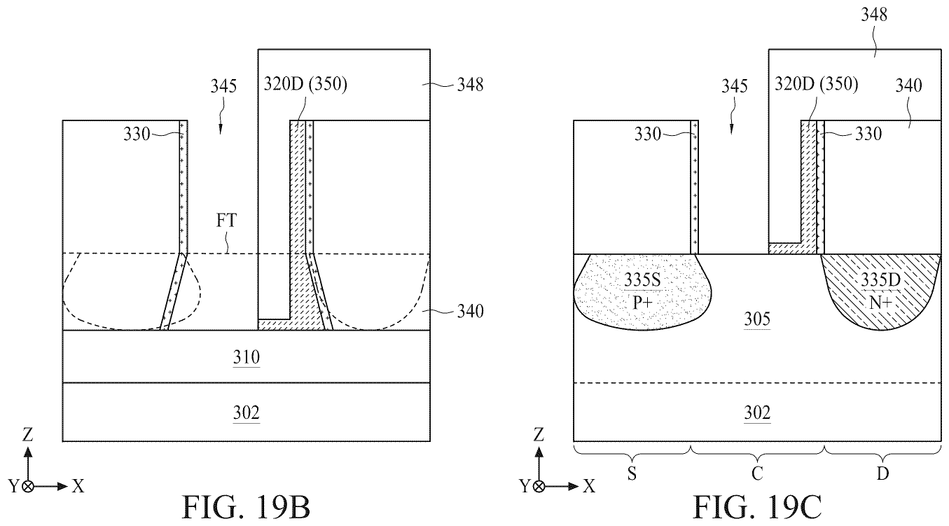

Referring to FIG. 12, FIGS. 18A-18C, and FIGS. 19A-19C, method 200 at block 235 includes removing the source-side oxide sidewall, such as source-side oxide sidewalls 320S. Drain-side oxide sidewall, such as drain-side oxide sidewalls 320D, remain to provide gate stacks with drain-side gate dielectrics, such as described herein. In FIGS. 18A-18C, such processing may include forming a mask 348 over device 300. Mask 348 is a patterned hard mask and/or a patterned resist that covers drain-side oxide sidewalls 320D and exposes source-side oxide sidewalls 320S. Mask 348 may further cover drain regions of device 300, which are adjacent to drain-side oxide sidewalls 320D, and expose source regions of device 300, which are adjacent to source-side oxide sidewalls 320S. In the depicted embodiment, mask 348 has an opening therein that exposes source-side oxide sidewalls 320S and source regions of device 300 that are adjacent thereto. Mask 348 is further formed in and partially covers/fills gate openings 345, such that gate openings 345 have a width W after forming mask 348. Width W may be adjusted/tuned (e.g., wider or narrower) to adjust/tune a length of a source-side gate dielectric and a length of the drain-side gate dielectric along the channel regions of fins 305.

In some embodiments, mask 348 is formed by forming a resist layer over device 300 (e.g., by spin coating) and performing a lithography process on the resist layer, thereby forming a patterned resist layer that covers drain-side oxide sidewalls 320D and drain regions adjacent thereto but exposes source-side oxide sidewalls 320S and source regions adjacent thereto. In some embodiments, mask 348 is formed by depositing a hard mask material over device 300 and performing a patterning process to remove portions of the hard mask material that cover source-side oxide sidewalls 320S and source regions adjacent thereto. The patterning process may include performing a lithography process to form a patterned resist layer that covers the hard mask material over drain-side oxide sidewalls 320D and drain regions adjacent thereto and exposes the hard mask material over source-side oxide sidewalls 320S and source regions adjacent thereto and performing an etching process to selectively remove the exposed hard mask material. A composition and/or a thickness of mask 348 is configured to resist an etching process used to remove source-side oxide sidewalls 320S.

In FIGS. 19A-19C, an etching process selectively removes source-side oxide sidewalls 320S with respect to gate spacers 330. For example, the etching process etches source-side oxide sidewalls 320S with no (or negligible) etching of gate spacers 330 and dielectric layer 340 over source regions of fins 305. In some embodiments, an etchant of the etching process etches source-side oxide sidewalls 320S (e.g., a dielectric material having a first composition) at a higher rate than gate spacers 330 and dielectric layer 340 (e.g., dielectric materials having a second composition and a third composition, respectively, that are both different than the first composition). Mask 348 is resistant to the etching process (e.g., mask 348 is an etch mask) and protects drain-side oxide sidewalls 330 (and dielectric layer 340 over drain regions of fins 305, such as depicted) from the etching process. The etching process may also selectively remove source-side oxide sidewalls 320S with respect to fins 305 and/or substrate isolation structures 310. For example, the etching process may selectively remove exposed portions of source-side oxide sidewalls 320S that extend over source-side portions of channel regions of fins 305 and/or over source-side portions of isolation regions of device 300. After the etching process, drain-side oxide sidewalls 320D and portions of drain-side oxide sidewalls 320D that extend over drain-side portions of channel regions of fins 305 and/or over drain-side portions of isolation regions of device 300 may be referred to as drain-side gate dielectric layers 350. The etching process is a dry etch, a wet etch, other suitable etch, or combinations thereof.

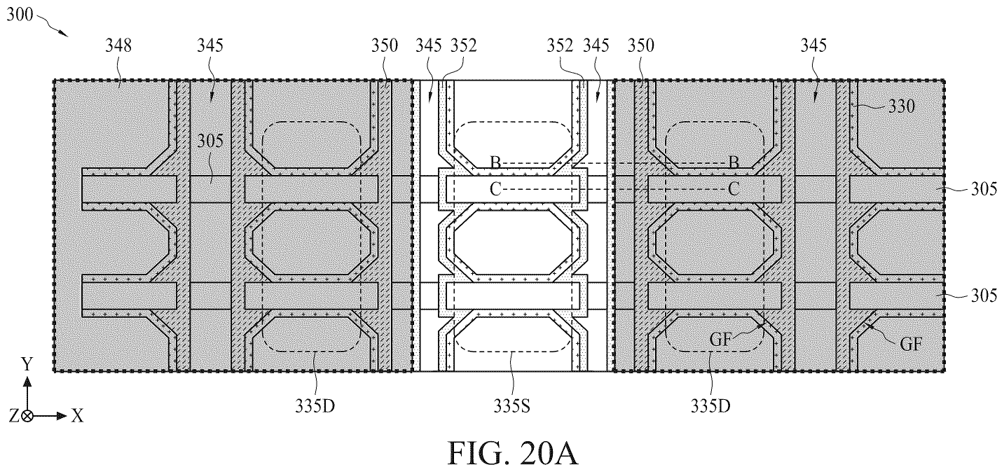

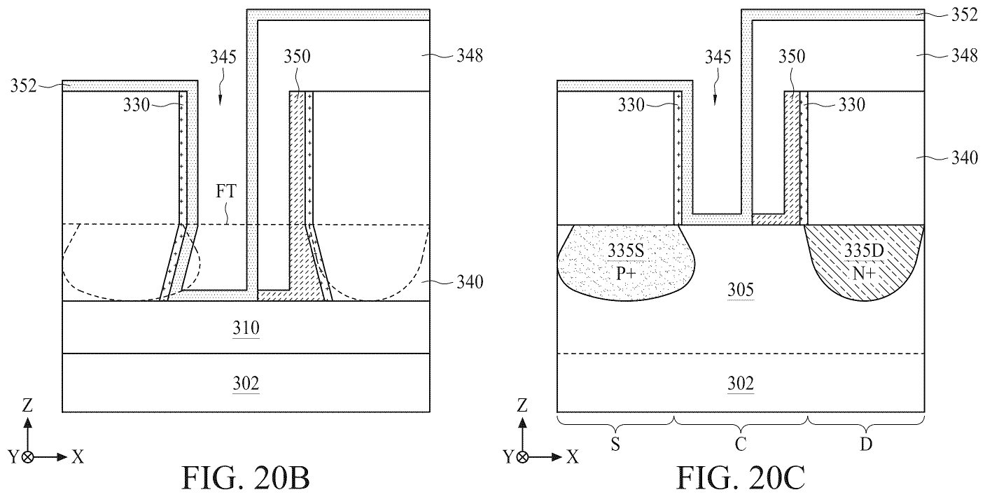

Referring to FIG. 12 and FIGS. 20A-20C, method 200 at block 240 includes forming a source-side gate dielectric in the gate opening. In FIGS. 20A-20C, a source-side gate dielectric layer 352 is formed in and partially fills gate openings 345. In the depicted embodiment, source-side gate dielectric layer 352 is formed before removing mask 348, such that source-side gate dielectric 352 is confined to source-sides of gate openings 345. In some embodiments, source-side gate dielectric layer 352 is formed after removing mask 348 by a selective growth/deposition process (e.g., high-k material may be selectively formed/grown on fins 305 and/or gate spacers 330 but not on drain-side oxide sidewalls 320S). Source-side gate dielectric layer 352 may be similar to source-side gate dielectric layer 136 described above. For example, source-side dielectric layer 352 includes a dielectric material having a dielectric constant that is higher than a dielectric constant of drain-side dielectric layers 350 (e.g., a dielectric constant of a dielectric material that includes silicon, oxygen, and nitrogen). In some embodiments, the dielectric material is HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. Source-side gate dielectric layer 352 is formed by ALD, CVD, PVD, oxidation-based deposition process, other suitable process, or combinations thereof. For example, an ALD process conformally deposits source-side gate dielectric layer 352, such that a thickness of source-side gate dielectric layer 352 is substantially uniform (conformal) over various surfaces. In some embodiments, source-side gate dielectric layer 352 is provided with thickness t1.

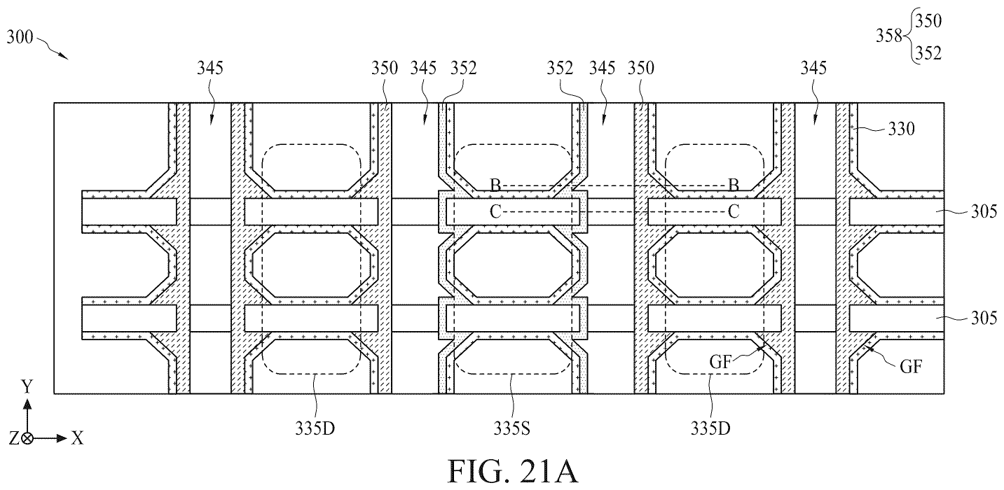

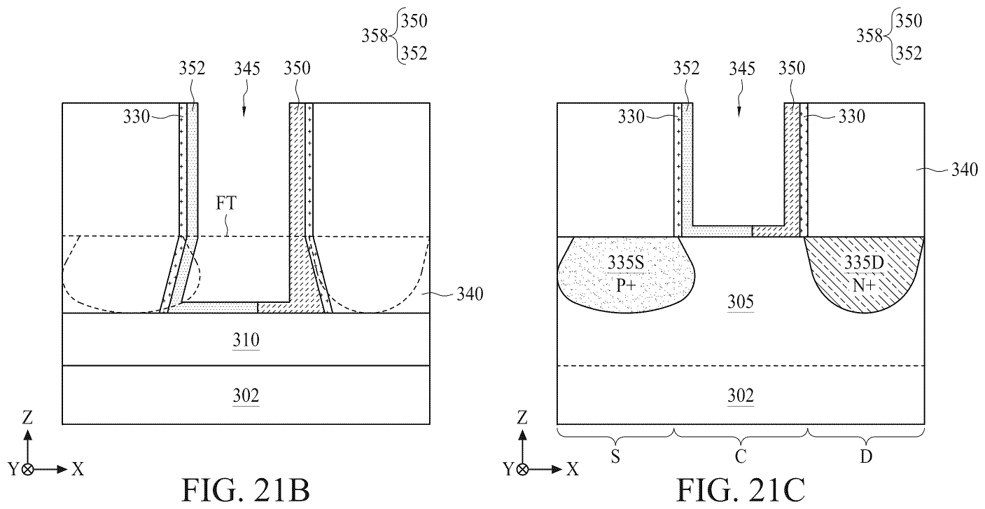

Referring to FIGS. 21A-21C, mask 348 is removed by a suitable process. For example, where mask 348 is a patterned resist, mask 348 may be removed by a resist stripping process and/or other suitable process. In another example, where mask 348 is a patterned hard mask, mask 348 may be removed by a suitable etching process, such as a reactive ion etching (RIE) process. Mask 348 is selectively removed with respect to source-side gate dielectric layer 352, drain-side gate dielectric layers 350, and dielectric layer 340, and portions of source-side gate dielectric layer 352 disposed on mask 348 are removed therewith. Device 300 is thus provided with gate dielectrics 358 that partially fill gate openings 345, and each gate dielectric 358 includes a respective source-side gate dielectric layer 352 and a respective drain-side gate dielectric layer 350, which may improve TFET performance as described herein.

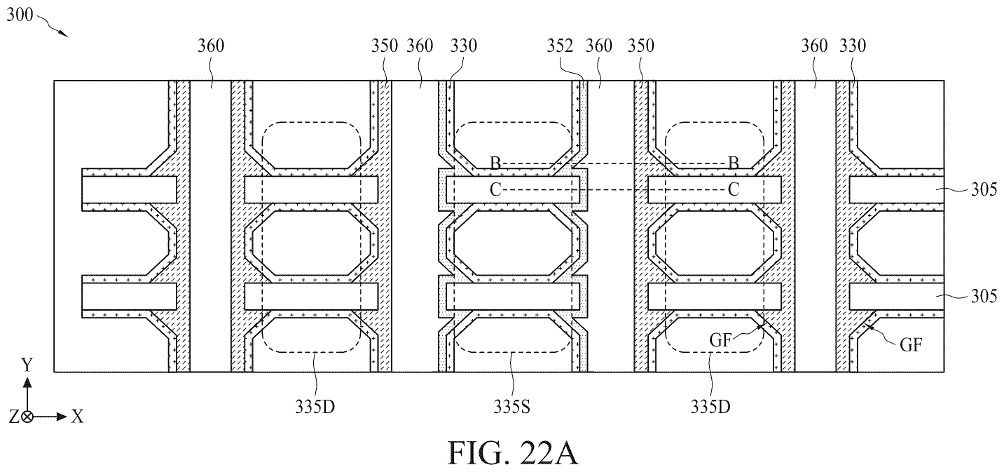

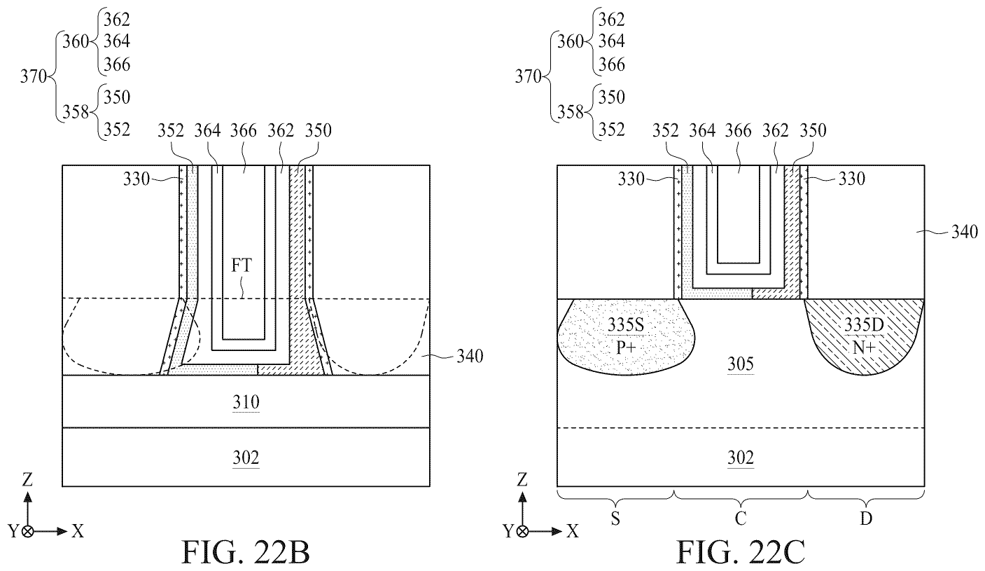

Referring to FIG. 12 and FIGS. 22A-22C, method 200 at block 245 includes forming a gate electrode over the source-side gate dielectric and the drain-side gate dielectric. The gate electrode fills a remainder of the gate opening. In FIGS. 22A-22C, gate electrodes 360 are formed in gate openings 345 over source-side gate dielectric layers 352 and drain-side gate dielectric layers 350, and gate electrodes 360 fill remainders of gate openings 345. In some embodiments, such as depicted, each gate electrode 360 includes a respective work function layer 362, a respective cap 364, and a respective bulk (fill) layer 366.

In some embodiments, gate electrodes 360 are formed by depositing a work function material over device 300 that partially fills gate openings 345, depositing a cap material over the work function material that partially fills gate openings 345, depositing a bulk/fill material over the work function material that fills remainders of gate openings 345, and performing a planarization process to remove excess gate materials, such as those disposed over dielectric layer 340. For example, a CMP process removes portions of the bulk/fill material (e.g., bulk layer 366), the cap material (e.g., cap 364), the work function material (e.g., work function layer 362), and gate dielectric material (e.g., source-side gate dielectric layers 352) that are disposed over dielectric layer 340. The CMP process may be performed until reaching and/or exposing a top surface of dielectric layer 340. Accordingly, device 300 is provided with gate stacks 370, each of which has a respective gate dielectric 358 (e.g., a respective source-side gate dielectric layer 352 and a respective drain-side gate dielectric layer 350) and a respective gate electrode 360 (e.g., a respective work function layer 362, a respective cap 364, and a respective bulk layer 366). Because drain-side oxide sidewalls 320D remain but source-side oxide sidewalls 320S are removed, gate stacks 370 have asymmetric gate footing, such as source-side gate footing GFS that is formed by gate dielectric 358 (e.g., source-side gate dielectric layer 352 thereof) and gate electrode 360 (e.g., work function layer 362 thereof) and a drain-side gate footing GFD that is formed by gate dielectric 358 (e.g., drain-side gate dielectric layer 350 thereof). In some embodiments, the CMP process may continue to reduce a thickness of dielectric layer 340, and correspondingly, a height of the gate structures (e.g., heights of gate stacks 370 and gate spacers 330 thereof). In the depicted embodiment, tops of the gate structures (e.g., tops of gate stacks 370) are substantially planar with a top of dielectric layer 340 after the planarization process, and remainders of the gate materials, which fill gate openings 345, form gate stacks 370. The work function material, the cap material, and the bulk/fill material may be deposited by ALD, CVD, PVD, other suitable process, or combinations thereof.

Work function layer 362 is an electrically conductive layer tuned to have a desired work function. Work function layer 362 may be an n-type work function metal (N-WFM) layer, a p-type work function metal (P-WFM) layer, or combinations thereof. An N-WFM layer (also referred to as an n-metal layer) includes an n-type work function material, which generally refers to an electrically conductive material tuned to have an n-type work function, and a p-WFM layer (also referred to as a p-metal layer) includes a p-type work function material, which generally refers to an electrically conductive material tuned to have a p-type work function. The n-type work function material may include a metal with a sufficiently low effective work function, such as aluminum, titanium, tantalum, zirconium, other n-metal, alloys thereof, or a combination thereof. In some embodiments, the N-WFM layer is a titanium aluminum layer, a titanium aluminum carbide layer, a tantalum carbide layer, a tantalum carbide nitride layer, or a tantalum silicon nitride. The p-type work function material may include a metal with a sufficiently high effective work function, such as titanium, tantalum, ruthenium, molybdenum, tungsten, platinum, other p-metal, alloys thereof, or a combination thereof. In some embodiments, the P-WFM layer is a titanium nitride layer, a titanium carbide layer, a titanium silicon nitride layer, a tantalum nitride layer, a tungsten carbonitride layer, or a molybdenum layer. In some embodiments, the work function layer has a multilayer structure, such as more than one N-WFM layer, more than one P-WFM layer, or an N-WFM layer(s) and a P-WFM layer(s).

Bulk/fill layer 366 includes an electrically conductive material, such as Al, W, Cu, Ti, Ta, polysilicon, other suitable metal(s) and/or alloys thereof, or combinations thereof. In some embodiments, bulk layer 366 is a tungsten layer formed by PVD or CVD. In some embodiments, bulk layer 366 is a fluorine-free tungsten (FFW) layer. In some embodiments, bulk layer 366 has a multilayer structure, such as a glue layer and a metal fill layer, such as a tungsten layer. The glue layer may include a material that promotes adhesion between adjacent layers, such as between work function layer 362/cap 264 and the subsequently formed metal fill layer, and/or that prevents or eliminates diffusion and/or reaction of constituents between adjacent layers. For example, the glue layer may include metal and nitrogen, such as TIN, TaN, W₂N, TiSiN, TaSiN, other suitable metal nitride material, or combinations thereof.

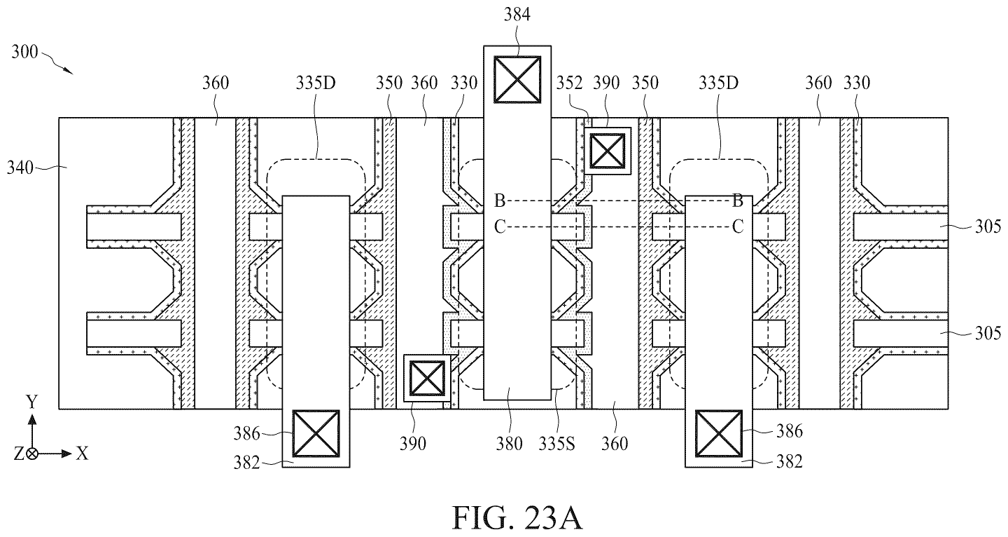

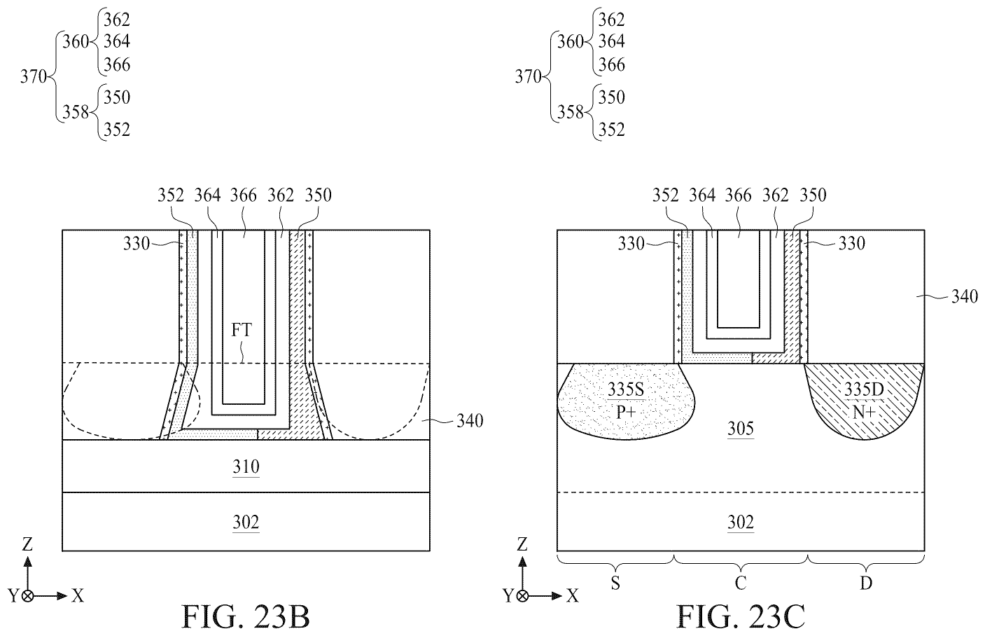

Referring to FIGS. 23A-23C, in some embodiments, processing may further include forming interconnects, such as gate interconnects, source interconnects, drain interconnects, or combinations thereof. For example, processing may include forming source contacts 380 to sources 335S, drain contacts 382 to drains 335D, source vias 384 to source contacts 380, drain vias 386 to drain contacts 382, and gate contacts/vias 390 to gate stacks 370 (e.g., to gate electrodes 360 thereof). In some embodiments, forming source/drain contacts includes forming a source/drain contact opening in dielectric layer 340 that exposes sources 335S or drains 335D and forming at least one electrically conductive layer (e.g., metal) in the source/drain contact openings. In some embodiments, the source/drain contact openings are formed by forming a patterned mask layer (e.g., an etch mask) over dielectric layer 340 and etching exposed portions of dielectric layer 340. In some embodiments, forming at least one electrically conductive layer in the source/drain contact opening includes forming a metal silicide layer over a source or a drain, depositing a barrier/liner layer that partially fills the source/drain contact opening, depositing a metal layer over the barrier/liner layer that fills remainders of the source/drain contact opening, and performing a planarization process to remove portions of the barrier/liner layer and/or the metal layer that are disposed over the top of dielectric layer 340.

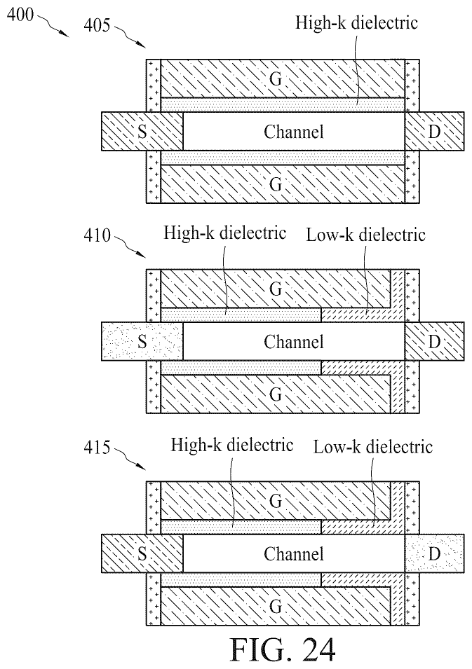

FIG. 24 depicts a device 400, in portion or entirety, that includes various transistors, such as the TFETs described herein, according to various aspects of the present disclosure. Device 400 may include a transistor 405, a transistor 410, and a transistor 415. Transistor 405 may be a metal-oxide-semiconductor (MOS) FET, transistor 410 may be a TFET, such as TFET 100 as depicted in FIG. 3, and transistor 415 may be a TFET, such as TFET 100 as depicted in FIG. 8. Transistor 405 has symmetric source/drains (e.g., sources and drains have the same conductivity type), while transistor 410 and transistor 415 have asymmetric source/drains (e.g., sources and drains have different conductivity types). In some embodiments, the asymmetric source/drains may include different materials, different conductivities, different profiles, different dimensions, or combinations thereof, while the symmetric source/drains may include the same materials, the same conductivities, the same profiles, the same dimensions, or combinations thereof. In some embodiments, transistor 405 has a symmetric gate stack (e.g., a high-k dielectric layer and a gate electrode (G)), while transistor 410 and transistor 415 have asymmetric gate stacks. The asymmetric gate stacks may have an asymmetric gate dielectric, an asymmetric gate electrode, asymmetric sidewalls, or combinations thereof. FIG. 24 has been simplified for the sake of clarity to better understand the inventive concepts of the present disclosure. Additional features may be added in device 400, and some of the features described below may be replaced, modified, or eliminated in other embodiments of device 400.

The present disclosure provides for many different embodiments. An exemplary tunnel field effect transistor includes a gate stack disposed over a semiconductor layer, a source disposed in the semiconductor layer, and a drain disposed in the semiconductor layer. The gate stack includes a gate electrode disposed over a gate dielectric. The gate stack is disposed between the source and the drain. The source has a first conductivity type, and the drain has a second conductivity type different than the first conductivity type. The gate stack is asymmetric. In some embodiments, the semiconductor layer is a semiconductor fin, the source and the drain are disposed in the semiconductor fin, and the gate stack wraps the semiconductor fin.

In some embodiments, the source extends under the gate stack and the drain does not extend under the gate stack. In some embodiments, the gate stack has a source-side gate footing and a drain-side gate footing. The source-side gate footing includes and/or is formed by the gate electrode and the gate dielectric, and the drain-side gate footing includes and/or is formed by the gate dielectric and is free of the gate electrode.

In some embodiments, the gate dielectric of the gate stack has a source-side gate dielectric and a drain-side gate dielectric that is different than the source-side gate dielectric. In some embodiments, the source-side gate dielectric has a first dielectric constant, the drain-side gate dielectric has a second dielectric constant, and the second dielectric constant is different than the first dielectric constant. In some embodiments, the source-side gate dielectric has a first thickness, the drain-side gate dielectric has a second thickness, and the second thickness is different than the first thickness. In some embodiments, the source-side gate dielectric forms a source-side sidewall of the gate stack and the drain-side gate dielectric forms a drain-side sidewall of the gate stack. In some embodiments, the source-side gate dielectric includes metal and oxygen, and the drain-side gate dielectric includes silicon, oxygen, and nitrogen.

Another exemplary tunnel field effect transistor includes a channel region, a source, a drain. The channel region is disposed between the source and the drain. The gate stack is disposed over the channel region. The gate stack includes a source-side gate dielectric, a drain-side gate dielectric, and a gate electrode disposed over the source-side gate dielectric and the drain-side gate dielectric. The source-side gate dielectric has a first dielectric constant, the drain-side gate dielectric has a second dielectric constant, and the first dielectric constant is greater than the second dielectric constant. The tunnel field effect transistor further includes a source-side gate spacer and a drain-side gate spacer disposed adjacent to the source-side gate dielectric and the drain-side gate dielectric, respectively.

In some embodiments, the channel region, the source, and the drain are disposed in a semiconductor fin, and the gate stack wraps the semiconductor fin. In some embodiments, the channel region is disposed in a semiconductor layer that extends the source and the drain, and the gate stack at least partially surrounds the semiconductor layer.

In some embodiments, a first length of the source-side gate dielectric along a top of the channel region is different than a second length of the drain-side gate dielectric along the top of the channel region. In some embodiments, the source-side gate dielectric has a first thickness, the drain-side gate dielectric has a second thickness, and the second thickness is greater than the first thickness. In some embodiments, a profile of the source and a profile of the gate stack provide a gate-source overlap, and a profile of the drain and the profile of the gate stack provide gate-drain underlap. In some embodiments, the source has bowed sidewalls and the drain has tapered sidewalls. In some embodiments, the gate stack has a source-side gate footing and a drain-side gate footing, the source-side gate footing includes the gate electrode and the source-side gate dielectric, and the drain-side gate footing includes the drain-side gate dielectric.

In some embodiments, a cross-sectional profile of the source is different than a cross-sectional profile of the drain. In some embodiments, a top profile of the source is different than a top profile of the drain. In some embodiments, a length of a longest portion of the source is greater than a length of a longest portion of the drain.

An exemplary method includes forming a dummy gate, forming gate spacers adjacent to the dummy gate, oxidizing the dummy gate to form a first oxide sidewall and a second oxide sidewall, forming a gate opening by removing the remainder of the dummy gate, masking the first oxide sidewall, forming a gate dielectric layer after removing the second oxide sidewall, and forming a gate electrode in the gate opening after unmasking the first oxide sidewall. Another exemplary method includes forming a dummy gate, oxidizing the dummy gate to form a first oxide sidewall and a second oxide sidewall, forming gate spacers adjacent to the first oxide sidewall and the second oxide sidewall, forming a gate opening by removing the remainder of the dummy gate, masking the first oxide sidewall, forming a gate dielectric layer after removing the second oxide sidewall, and forming a gate electrode in the gate opening after unmasking the first oxide sidewall. In some embodiments, the methods further include forming a source and a drain after oxidizing the dummy gate and before removing the remainder of the dummy gate. In some embodiments, the masking the first oxide sidewall includes masking a drain-side oxide sidewall and the removing the second oxide sidewall includes removing a source-side oxide sidewall. In some embodiments, the gate dielectric layer is formed before unmasking the first oxide sidewall. In some embodiments, the methods further include forming the dummy gate to have a source-side gate footing and a drain-side gate footing, and the oxidizing of the dummy gate is performed until the drain-side gate footing is formed by the first oxide sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A tunnel field effect transistor comprising:
a semiconductor layer that extends lengthwise along a first direction;
a gate stack that extends lengthwise along a second direction different than the first direction, wherein the gate stack is disposed over a first portion of the semiconductor layer, wherein the gate stack includes a gate electrode and a gate dielectric;
a source and a drain disposed in a second portion and a third portion, respectively, of the semiconductor layer, wherein the gate stack is disposed between the source and the drain along the first direction, the source has a first conductivity type, and the drain has a second conductivity type different than the first conductivity type; and
wherein, in a top view, an overlap is between the gate electrode and the source and an underlap is between the gate electrode and the drain.
